(19) United States
(12) Patent Application Publication
(10) Pub. No.: US 2006/0174833 A1
(43) Pub. Date: Aug. 10, 2006

(54) Substrate treating apparatus and method of substrate treatment

(75) Inventors: Kazuyoshi Yamazaki, Yamanashi (JP); Shintaro Aoyama, Yamanashi (JP); Masanobu Igeta, Yamanashi (JP); Hiroshi Shinriki, Chiba (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Tokyo Electron Limited, Tokyo (JP)

(21) Appl. No.: 10/549,285

(22) PCT Filed: Dec. 8, 2003
(86) PCT No.: PCT/JP03/15679

§ 371 Date: Sep. 16, 2005

(30) Foreign Application Priority Data
Mar. 17, 2003 (JP) 2003-072650

(51) Int. Cl. C23C 16/00; H01L 21/31

(52) U.S. Cl. 118/719; 438/786

(57) ABSTRACT

It is intended to efficiently nitride an extremely thin oxide film or oxynitride film of 0.4 nm or less thickness while minimizing a film increase. In particular, oxygen radicals are generated through oxygen radical generating unit so as to oxidize a silicon substrate with the generated oxygen radicals, thereby forming an oxide film on the silicon substrate, and further nitrogen radicals are generated through nitrogen radical generating unit so as to nitride the surface of the oxide film, thereby forming an oxynitride film.

### FIELD OF THE INVENTION

The present invention relates to a substrate processing apparatus and a substrate processing method; and particularly, to a substrate processing apparatus and a substrate processing method for manufacturing an ultra miniaturized high speed semiconductor device having a high-K film.

### BACKGROUND OF THE INVENTION

With the advancement in the miniaturization process technology, it has become feasible to use a gate length of 0.1 μm or less in an ultra high speed semiconductor device. Generally, the operating speed of a semiconductor device is improved with the miniaturization thereof. However, in such a highly miniaturized semiconductor device, the thickness of a gate insulating film needs to be reduced in proportion to the reduction in the gate length in accordance with the scaling rule.

In case the gate length is reduced to 0.1 μm or less, the thickness of the gate insulating film needs to be 1˜2 nm or less on a conventional thermal oxide film basis. However, such an extremely thin gate insulating film suffers from an increased gate leakage current resulting from an increase in the tunneling current.

Accordingly, it has been proposed to employ a high-K dielectric material having a substantially higher dielectric constant than the thermal oxide film for use as a gate insulating film. Specifically, Ta₂O₅ or Al₂O₃, ZrO₂, HfO₂, and ZrSiO₄ or HfSiO₄ have been tried for such purpose since their respective film thicknesses are small in terms of that of an SiO₂ film despite their large actual thickness. With the use of such a high-K dielectric material, a gate insulating film with a physical film thickness of about 10 nm can be employed even when the gate length for use in an ultra high speed semiconductor device is very short, e.g., 0.1 μm or less, thereby preventing the gate leakage current resulting from the tunneling effect.

A Ta₂O₅ film is known to be formed through a CVD process from gaseous raw materials of Ta(OC₂H₅)₅ and O₂. Typically, the CVD process is conducted in a depressurized environment and at about 480° C. or higher temperature. The Ta₂O₅ film formed in such manner is then subject to a heat treatment in the presence of oxygen for crystallization and this compensates for the oxygen deficiency in the film. The Ta₂O₅ film in its crystallized state possesses a large dielectric constant.

To enhance a carrier mobility in a channel region, it is preferable to interpose an extremely thin base oxide film having the thickness of 1 nm or less, preferably 0.8 nm or less, between a high-K dielectric gate oxide film and a silicon substrate. The base oxide film needs to be very thin since the merit of employing the high-K dielectric film as a gate insulating film might be lost otherwise. Such an extremely thin base oxide film is required to cover the surface of the silicon substrate uniformly, without forming defects such as interface states.

Conventionally, the thin gate oxide film used to be typically formed by way of performing a rapid thermal oxidation (RTO) processing on the silicon substrate. When forming a thermal oxide film of a desired thickness of 1 nm or less, it is necessary to reduce a processing temperature used at the time of film formation. However, since the thermal oxide film formed at such a low temperature is likely to contain defects such as interface states and the like, it is inappropriate to be used for the base oxide film of the high-K gate insulating film.

Further, as a relevant reference, there is Bruce E. Deal, J. Electrochem. Soc. 121.198C (1974).

### SUMMARY OF THE INVENTION

However, there has been a difficulty in forming the base oxide film uniformly and stably with a thickness of 1 nm or less, e.g., 0.8 nm or less, or about 0.3˜0.4 nm. In case where the film thickness is 0.3˜0.4 nm, the oxide film has only a film thickness equivalent to 2˜3 atomic layers.

Further, conventionally, it has been pointed out that if a metal oxide film having a small number of covalent bonds, i.e., having a low stiffness, is directly formed on a surface of a silicon single crystal having a large number of covalent bonds, i.e., having a high stiffness, an interface between the silicon substrate and the metal oxide film becomes kinetically unstable, so that defects may be generated (e.g., G. Lucovisky, et al., Appl. Phys. Lett. 74, pp. 2005, 1999). For avoiding this problem, it has been proposed that an oxynitride layer including one atomic layer of nitrogen introduced therein is formed as a transition layer between the silicon substrate and the metal oxide film. Further, if such an oxynitride film is formed as the base oxide film of the high-K gate insulating film, it is considered to be effective for suppressing an interdiffusion between a metal element or an oxygen in the high-K gate insulating film and a silicon forming the silicon substrate, or suppressing a diffusion of dopants from an electrode.

FIG. 1 describes an example of a substrate processing apparatus 100 for forming an oxide film on a silicon substrate and then forming an oxynitride film.

Referring to FIG. 1, the substrate processing apparatus 100 having a processing vessel 101 whose inside is exhausted through a gas exhaust port 103 connected to a gas exhaust unit 104, e.g., a dry pump or the like, includes therein a substrate supporting table for supporting a wafer W0 of a substrate to be processed.

The wafer W0 mounted on the substrate supporting table 102 is oxidized or nitrided by radicals supplied from a remote plasma radical source 105 installed on a sidewall surface of the processing vessel 101, to thereby form an oxide or an oxynitride film on the wafer W0.

The remote plasma radical source dissociates an oxygen gas or a nitrogen gas by using a high frequency plasma to supply oxygen radicals or nitrogen radicals onto the wafer W0.

When the silicon substrate is first oxidized in the processing vessel and then is subject to a nitridation process in the corresponding processing vessel to form such an oxynitride film, an influence of a small amount of impurities such as oxygen, moisture, and the like, remaining in the processing vessel may not be negligible. Further, an oxidation reaction during the nitridation process can make the oxide film grow to thereby cancel an effect of using the high-K gate insulating film.

Conventionally, it has been difficult to stably nitride with good reproducibility such an extremely thin oxynitride film without accompanying a film growth due to the oxidation.

Further, there has been proposed a substrate processing apparatus in which an oxygen radical generation unit for producing oxygen radicals is separated from a nitrogen radical generation unit for producing nitrogen radicals.

FIG. 2 shows an example of a substrate processing apparatus 110 having two radical generation units.

Referring to FIG. 2, the substrate processing apparatus 110 having a processing vessel 111 whose inside is exhausted through a gas exhaust port 119 connected to a gas exhaust unit 120, e.g., a dry pump and the like, and in which a substrate supporting table 118 is provided, is configured such that a wafer W0 mounted on a substrate supporting table 118 can be oxidized by oxygen radicals and then nitrided by nitrogen radicals.

On an upper wall portion of the processing vessel 111, there are provided an ultraviolet light source 113 and a transmission window 114 transmitting an ultraviolet light, and it is configured such that an oxygen gas to be supplied from a nozzle 115 is dissociated by the ultraviolet light to generate oxygen radicals.

By the oxygen radicals formed above, a surface of the silicon substrate is oxidized to form an oxide film thereon.

Further, a remote plasma radical source 116 is installed on a sidewall of the processing vessel 111, and a nitrogen gas is dissociated by a high frequency plasma, so that nitrogen radicals are supplied into the processing vessel 111, and the oxide film on the wafer W0 is nitrided to form an oxynitride film.

As described above, there has been proposed a substrate processing apparatus in which an oxygen radical generation unit is separated from a nitrogen radical generation unit. By using the substrate processing apparatus, it is possible to form an oxide film having a film thickness of about 0.4 nm on the silicon substrate, and to form an oxynitride film by further nitriding it.

Meanwhile, in the substrate processing apparatus for sequentially performing the oxidation and the nitridation process on the silicon substrate, there is a demand for performing the oxidation and the nitridation process by using the remote plasma radical source.

Further, for suppressing an influence of the residual oxygen and thus eliminating the influence of the film growth due to the oxidation, if possible, a process for reducing the residual oxygen is required, such as a purge operation and the like, in which an inside of the processing vessel is vacuum-exhausted after the oxidation process and filled with an inactive gas, and then, a vacuum exhaustion and an operation for filling the inactive gas are carried out repeatedly, even in case of using the substrate processing apparatus of FIG. 2, resulting in a reduction of throughput and a decrease in productivity.

It is, therefore, a general object of the present invention to provide a new and useful substrate processing apparatus and a substrate processing method capable of resolving the aforementioned problems.

Specifically, it is an object of the present invention to provide a substrate processing apparatus and a substrate processing method having a good productivity, wherein an oxynitride film can be formed while suppressing a film growth of the oxide film during corresponding nitridation by forming on a surface of a silicon substrate an extremely thin oxide film having, typically, a thickness equivalent to 2˜4 or less atomic layers, and nitriding it.

In order to achieve the above objects, the present invention provides, as defined in claim 1, a substrate processing apparatus comprising: a processing vessel forming a processing space; a rotatable supporting table for supporting a substrate to be processed in the processing space; a rotation mechanism of the supporting table; a nitrogen radical generation unit, provided at an end portion of the processing vessel at a first side of the supporting table, for forming nitrogen radicals by a high frequency plasma and supplying the nitrogen radicals into the processing space, the nitrogen radicals flowing along a surface of the substrate to be processed from the first side to a second side, the second side facing the first side with the substrate to be processed placed therebetween; an oxygen radical generation unit, provided at the end portion at the first side, for forming oxygen radicals by a high frequency plasma and supplying the oxygen radicals into the processing space, the oxygen radicals flowing along the surface of the substrate to be processed from the first side to the second side; and a gas exhaust path, provided at an end portion at the second side, to exhaust the processing space, wherein the nitrogen radicals and the oxygen radicals flow towards the gas exhaust path from the nitrogen radical generation unit and the oxygen radical generation unit while forming a nitrogen radical flow path and an oxygen radical flow path along the surface of the substrate to be processed, respectively.

Further, the present invention provides, as defined in claim 2, the substrate processing apparatus according to claim 1, wherein the nitrogen radical generation unit includes a first gas passageway and a first high frequency plasma generation unit formed at a part of the first gas passageway to excite a nitrogen gas passing therethrough into a plasma; and the oxygen radical generation unit includes a second gas passageway and a second high frequency plasma generation unit formed at a part of the second gas passageway to excite an oxygen gas passing therethrough into a plasma, wherein the first and the second gas passageway are in communication with the processing space.

Still further, the present invention provides, as defined in claim 3, the substrate processing apparatus according to claim 1, wherein the nitrogen radical flow path and the oxygen radical flow path are substantially parallel to each other.

Still further, the present invention provides, as defined in claim 4, the substrate processing apparatus according to claim 1, wherein the nitrogen radical generation unit is installed to allow the distance between a center of the nitrogen radical flow path and that of the substrate to be processed to be 40 mm or less.

Still further, the present invention provides, as defined in claim 5, the substrate processing apparatus according to claim 1 wherein the oxygen radical generation unit is installed to allow the distance between a center of the oxygen radical flow path and that of the substrate to be processed to be 40 mm or less.

Still further, the present invention provides, as defined in claim 6, the substrate processing apparatus according to claim 1, wherein a center of the nitrogen radical flow path intersects with that of the oxygen radical flow path substantially at a center of the substrate to be processed.

Still further, the present invention provides, as defined in claim 7, the substrate processing apparatus according to claim 1, wherein there is provided a flow adjusting plate interfering with the nitrogen radical flow path to change a direction thereof.

Still further, the present invention provides, as defined in claim 8, the substrate processing apparatus according to claim 1, wherein there is provided a flow adjusting plate interfering with the oxygen radical flow path to change a direction thereof.

Still further, the present invention provides, as defined in claim 9, a substrate processing method for use in a substrate processing apparatus, which includes a processing vessel forming a processing space and having a supporting table for supporting a substrate to be processed in the processing space; a first radical generation unit for supplying first radicals into the processing vessel, the first radicals flowing along a surface of the substrate to be processed from a first side of the processing vessel to a second side that faces the first side with the substrate to be processed placed therebetween; and a second radical generation unit for supplying second radicals into the processing space, the second radicals flowing along the surface of the substrate to be processed from the first side to the second side, the method comprising: a first process of processing the substrate to be processed by supplying the first radicals from the first radical generation unit into the processing space while introducing a purge gas purging the second radical generation unit into the processing space from the second radical generation unit; and a second process of processing the substrate to be processed by introducing the second radicals from the second radical generation unit into the processing space.

Still further, the present invention provides, as defined in claim 10, the substrate processing method according to claim 9, wherein the substrate to be processed is a silicon substrate; and, in the first process, the surface of the silicon substrate is oxidized by the first radicals to form an oxide film, the first radicals being oxygen radicals.

Still further, the present invention provides, as defined in claim 11, the substrate processing method according to claim 10, wherein, in the second process, a surface of the oxide film is nitrided by the second radicals to form an oxynitride film, the second radicals being nitrogen radicals.

Sill further, the present invention provides, as defined in claim 12, the substrate processing method according to claim 9, wherein the first and the second radicals are supplied by being carried by a gas stream flowing from the first side to the second side along the surface of the substrate to be processed, and exhausted at the second side.

Sill further, the present invention provides, as defined in claim 13, the substrate processing method according to claim 9, wherein the first radical generation unit forms oxygen radicals by a high frequency plasma.

Sill further, the present invention provides, as defined in claim 14, the substrate processing method according to claim 9, wherein the first radical generation unit includes an ultraviolet light source forming oxygen radicals.

Sill further, the present invention provides, as defined in claim 15, the substrate processing method according to claim 9, wherein the second radical generation unit forms nitrogen radicals by a high frequency plasma.

Sill further, the present invention provides, as defined in claim 16, the substrate processing method according to claim 15, wherein the second radical generation unit includes a gas passageway, and a high frequency plasma generation unit formed at a part of the gas passageway to excite a nitrogen gas passing therethrough into a plasma.

Sill further, the present invention provides, as defined in claim 17, the substrate processing method according to claim 16, wherein the purge gas is supplied through the gas passageway.

Sill further, the present invention provides, as defined in claim 18, the substrate processing method according to claim 9, wherein the purge gas is an inactive gas.

Still further, the present invention provides, as defined in claim 19, a substrate processing method comprising: a first process for performing a first processing on a substrate to be processed in a processing vessel; a second process for unloading the substrate from the processing vessel; a third process for performing an oxygen removal process from the processing vessel; a fourth process for loading the substrate into the processing vessel; and a fifth process for performing a second processing on the substrate.

Still further, the present invention provides, as defined in claim 20, the substrate processing method according to claim 19, wherein, in the oxygen removal process, a processing gas is excited into a plasma and introduced into the processing vessel, and the processing gas is exhausted from the processing vessel.

Still further, the present invention provides, as defined in claim 21, the substrate processing method according to claim 20, wherein the processing gas is an inactive gas.

Still further, the present invention provides, as defined in claim 22, the substrate processing method according to claim 19, wherein the substrate to be processed is a silicon substrate, and the first processing is an oxidation process for oxidizing a surface of the silicon substrate to form an oxide film.

Still further, the present invention provides, as defined in claim 23, the substrate processing method according to claim 22, wherein the second processing is a nitridation process for nitriding the oxide film to form an oxynitride film.

Still further, the present invention provides, as defined in claim 24, the substrate processing method according to claim 23, wherein the processing vessel has an oxygen radical generation unit and a nitrogen radical generation unit; the oxidation process is carried out by oxygen radicals formed by the oxygen radical generation unit; and the nitridation process is performed by nitrogen radicals formed by the nitrogen radical generation unit.

Still further, the present invention provides, as defined in claim 25, the substrate processing method according to claim 20, wherein the plasma excitation is carried out in the nitrogen radical generation unit, and a processing gas excited into a plasma is introduced from the nitrogen radical generation unit into the processing vessel.

Still further, the present invention provides, as defined in claim 26, the substrate processing method according to claim 24, wherein the oxygen radicals and the nitrogen radicals flow along the substrate to be processed, and are exhausted from a gas exhaust port installed at an opposite side to the oxygen radical generation unit and the nitrogen radical generation unit along a diametrical direction of the substrate to be processed, which is mounted in the processing vessel.

Still further, the present invention provides, as defined in claim 27, the substrate processing method according to claim 19, wherein the processing vessel is connected to a cluster substrate processing system in which a plurality of substrate processing apparatus are connected to a transfer chamber.

Still further, the present invention provides, as defined in claim 28, the substrate processing method according to claim 27, wherein the substrate is transferred from the processing vessel to the substrate transfer chamber in the second processing.

Still further, the present invention provides, as defined in claim 29, the substrate processing method according to claim 27, wherein the substrate is mounted in the substrate transfer chamber in the third processing.

Still further, the present invention provides, as defined in claim 30, the substrate processing method according to claim 27, wherein the substrate is transferred from the transfer chamber to the substrate processing vessel in the fourth processing.

In accordance with the present invention having such a configuration, when forming an extremely thin base oxide film including an oxynitride film on a silicon substrate in a processing vessel, such a phenomenon that residues, e.g., an oxygen, an oxygen compound and the like, which have been used for forming the base oxide film, facilitate an oxidation of the silicon substrate when forming the oxynitride film to thereby grow the base oxide film is suppressed. Further, productivity can be improved.

As a result, it is possible to form an extremely thin base oxide film suitable to be used for a semiconductor device and to form an oxynitride film having a desired nitrogen concentration on the base oxide film, with an excellent productivity.

As described above, in accordance with the present invention, when forming an extremely thin base oxide film including an oxynitride film on a silicon substrate in a processing vessel, such a phenomenon that residues, e.g., an oxygen, an oxygen compound and the like, which have been used for forming the base oxide film, facilitate an oxidation of the silicon substrate when forming the oxynitride film to thereby grow the base oxide film is suppressed. Further, productivity can be improved.

As a result, it is possible to form an extremely thin base oxide film appropriate to be used for a semiconductor device and to form an oxynitride film having a desired nitrogen concentration on the base oxide film, with an excellent productivity.

### BRIEF DESCRIPTION OF THE DRAWINGS

FIG. 1 offers a (first) view for schematically showing a conventional substrate processing apparatus.

FIG. 2 describes a (second) view for schematically showing a conventional substrate processing apparatus.

FIG. 3 is a schematic view showing a configuration of a semiconductor device.

FIG. 4 sets forth a (first) view for schematically showing a substrate processing apparatus in accordance with the present invention.

FIG. 5 presents a configuration of a remote plasma source to be used for the substrate processing apparatus of FIG. 4.

FIGS. 6A and 6B are of a (first) side view and a (first) plane view, respectively, showing a substrate oxidation process to be carried out by using the substrate processing apparatus of FIG. 4.

FIGS. 7A and 7B are of a side view and a plane view, respectively, showing a nitridation process of an oxide film, which is carried out by using the substrate processing apparatus of FIG. 4.

FIG. 8 depicts a view typically showing a nitridation state of a substrate to be processed.

FIG. 9 describes a film thickness variance of an oxynitride film of a substrate to be processed.

FIGS. 10A through 10C offer install methods of a remote plasma source.

FIG. 11 shows a relationship between a film thickness and a nitrogen concentration in cases of a large and a small influence of a residual oxygen when forming an oxynitride film.

FIGS. 12A and 12B are of a (second) side view and a (second) plane view, respectively, showing a substrate oxidation process to be carried out by using the substrate processing apparatus of FIG. 4.

FIG. 13 presents a (second) view for schematically showing a substrate processing apparatus in accordance with the present invention.

FIGS. 14A and 14B are of a (first) side view and a (first) plane view, respectively, showing a substrate oxidation process to be carried out by using the substrate processing apparatus of FIG. 13.

FIGS. 15A and 15B are of a side view and a plane view, respectively, showing a nitridation process of an oxide film, which is carried out by using the substrate processing apparatus of FIG. 13.

FIGS. 16A and 16B are of a side view (second) and a plane view (second), respectively, showing a substrate oxidation process to be carried out by using the substrate processing apparatus of FIG. 13.

FIG. 17 illustrates a flowchart of a substrate processing method in accordance with a ninth embodiment of the present invention.

FIG. 18 is a schematic view showing a configuration of a cluster type substrate processing system 50 in accordance with a tenth embodiment of the present invention.

FIG. 19 provides a relationship between a film thickness and a nitrogen concentrate, in case where a base oxide film is formed by the substrate processing method of the ninth embodiment and an oxynitride film is formed by nitriding the base oxide film.

FIG. 20 offers a relationship between a film thickness and a nitrogen concentrate under different conditions, in case where a base oxide film is formed on a silicon substrate by using the substrate processing apparatus of FIG. 13 and an oxynitride film is formed by nitriding the base oxide film.

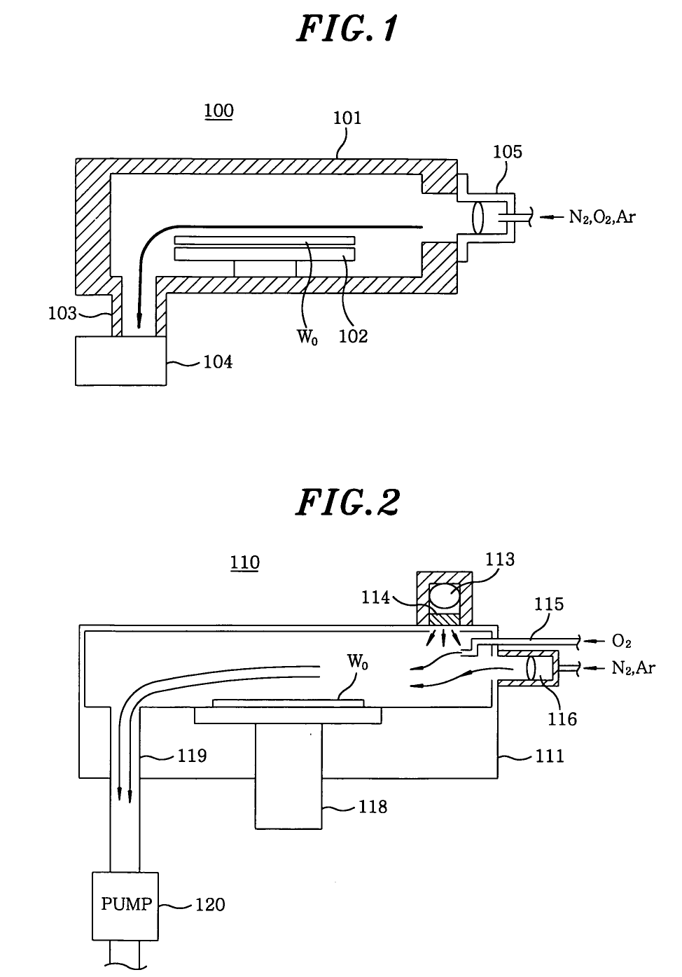

### DETAILED DESCRIPTION OF THE PREFERRED EMBODIMENT

Next, preferred embodiments of the present invention will be described with reference to the accompanying drawings.

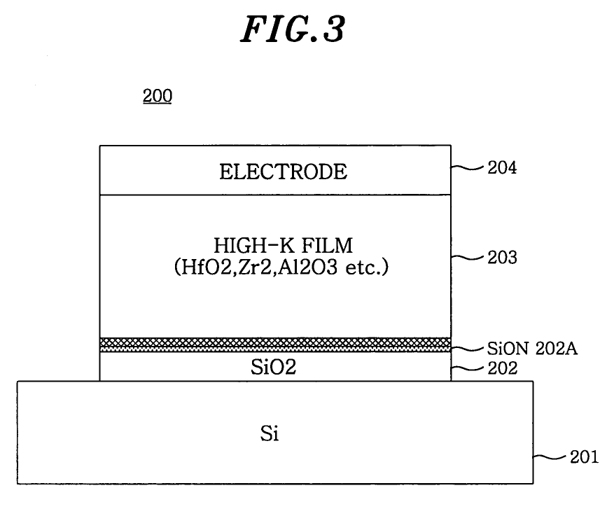

First, an example of a semiconductor device to be formed by a substrate processing apparatus and a substrate processing method in accordance with the present invention is shown in FIG. 3.

Referring to FIG. 3, a semiconductor device 200 is formed on a silicon substrate 201; on the silicon substrate 201, there is formed a high-K gate insulating film 203 such as Ta₂O₅, Al₂O₃, ZrO₂, HfO₂, HfSiO₄ or the like, via a thin base oxide film 202; and a gate electrode 204 is formed on the high-K gate insulating film 203.

In the semiconductor device 200 of FIG. 3, nitrogen (N) is doped to form an oxynitride film 202A on a surface portion of the base oxide film 202 within a range where an interface between the silicon substrate 201 and the base oxide film 202 can be kept flat. By forming on the base oxide film 202 the oxynitride film 202A having a dielectric constant greater than that of a silicon oxide film, it is possible to further reduce a conversion film thickness of a thermal oxide film of the base oxide film 202.

Hereinafter, each preferred embodiment of a substrate processing apparatus and a substrate processing method in accordance with the present invention will be discussed, wherein an influence of a small amount of impurities such as oxygen, moisture and the like, remaining in a processing vessel, is eliminated when forming the base oxide film 202 in the processing vessel and then forming the oxynitride film 202A in the corresponding processing vessel. Thus, the film growth of the oxide film due to an oxidation reaction during the nitridation process can be suppressed, and a substrate processing can be performed efficiently.

### First Embodiment

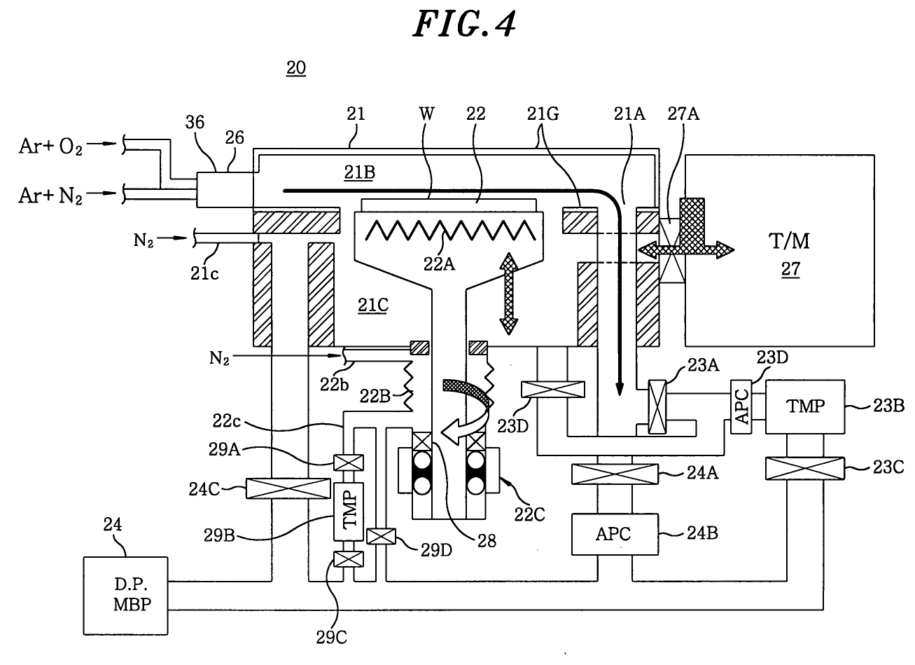

FIG. 4 describes a schematic configuration of a substrate processing apparatus 20 for forming an extremely thin base oxide film 202 including an oxynitride film 202A on a silicon substrate 201, in accordance with a first embodiment of the present invention.

Referring to FIG. 4, the substrate processing apparatus 20 has a substrate supporting table 22, which accommodates therein a heater 22A and vertically moves between a process position and a substrate loading/unloading position; and includes a processing vessel 21 forming a processing space 21B together with the substrate supporting table 22. The substrate supporting table 22 is rotated by a driving mechanism 22C. Further, an inner wall surface of the processing vessel 21 is coated with an inner liner 21G made of a quartz glass, whereby a metal contamination on a substrate to be processed from an exposed metal surface is suppressed to a level of 1×10¹⁰ atoms/cm² or less.

Further, a magnetic seal 28 formed in a coupling portion of the substrate supporting table 22 and the driving mechanism 22C separates a magnetic seal chamber 22B maintained at a vacuum atmosphere from the driving mechanism 22C formed under an atmospheric environment. The substrate supporting table 22 is supported to rotate freely since the magnetic seal 28 is a liquid.

In a state shown in the drawing, the substrate supporting table 22 is in the process position, and a loading/unloading chamber 21C for loading and unloading the substrate to be processed is formed in a lower side. The processing vessel 21 is coupled to a substrate transfer mechanism 27 through a gate valve 27A, and a substrate W to be processed is transferred from the substrate transfer mechanism 27 to the substrate supporting table 22 through the gate valve 27A while the substrate supporting table 22 is lowered to the loading/unloading 21C. Further, a processed substrate W is transferred from the substrate supporting table 22 to the substrate transfer mechanism 27.

In the substrate processing apparatus 20 of FIG. 4, a gas exhaust port 21A is formed in a part close to the gate valve 27A of the processing vessel 21, and a turbo molecular pump 23B is coupled to the gas exhaust port 21A through a valve 23A and an APC (automatic pressure controller) 23D. Further, a pump 24 formed by coupling a dry pump and a mechanical booster pump is coupled to the turbo molecular pump 23B via a valve 23C, and an inner pressure of the processing space 21B can be depressurized in the range from 1.33×10⁻¹ to 1.33×10⁻⁴ Pa (10⁻³ to 10⁻⁶ Torr) by driving the turbo molecular pump 23B and the dry pump 24.

Meanwhile, the gas exhaust port 21A is directly coupled to the pump 24 via the valve 24A and the APC 24B and, the processing space is depressurized to a pressure in the range from 1.33 Pa to 1.33 kPa (0.01 to 10 Torr) through the pump 24, by opening the valve 24A.

In the processing vessel 21, remote plasma sources 26 and 36 are installed opposite to the gas exhaust port 21A with respect to the substrate W to be processed.

In the remote plasma source 36, an oxygen gas and an inactive gas such as Ar and the like are supplied together and activated by a plasma, to thereby form oxygen radicals. The oxygen radicals formed above flow along the surface of the substrate W to be processed and oxidizes the surface of the rotating substrate.

By this, a radical oxide film can be formed on the surface of the substrate W to be processed, wherein the film thickness is 1 nm or less, specifically about 0.4 nm that is equivalent to a thickness of 2˜3 atomic layers.

In the substrate processing apparatus 20 of FIG. 4, a purge line 21c purging the loading/unloading chamber 21C by a nitrogen gas is provided, and a purge line 22b purging the magnetic seal chamber 22B by the nitrogen gas and a gas exhaust line 22c thereof are installed.

More specifically, the gas exhaust line 22c is coupled to the turbo molecular pump 29B via the valve 29A, and the turbo molecular pump 29B is coupled to the pump 24 via the valve 29C. Further, the gas exhaust line 22c is directly coupled to the pump 24 via the valve 29D, whereby the magnetic seal chamber 22B can be maintained at various pressures.

The loading/unloading chamber 21C is exhausted through the valve 24C by the pump 24, or exhausted through the valve 23D by the turbo molecular pump 23B. For prevent any contamination in the processing space 21B, the loading/unloading chamber 21C is maintained at a lower pressure than that of the processing space 21B, and the magnetic seal chamber 22B is subject to a differential pumping to thereby be maintained at a much lower pressure than that of the loading/unloading chamber 21C.

Subsequently, the remote plasma sources 26 and 36 to be used for the present substrate processing apparatus will now be discussed in detail.

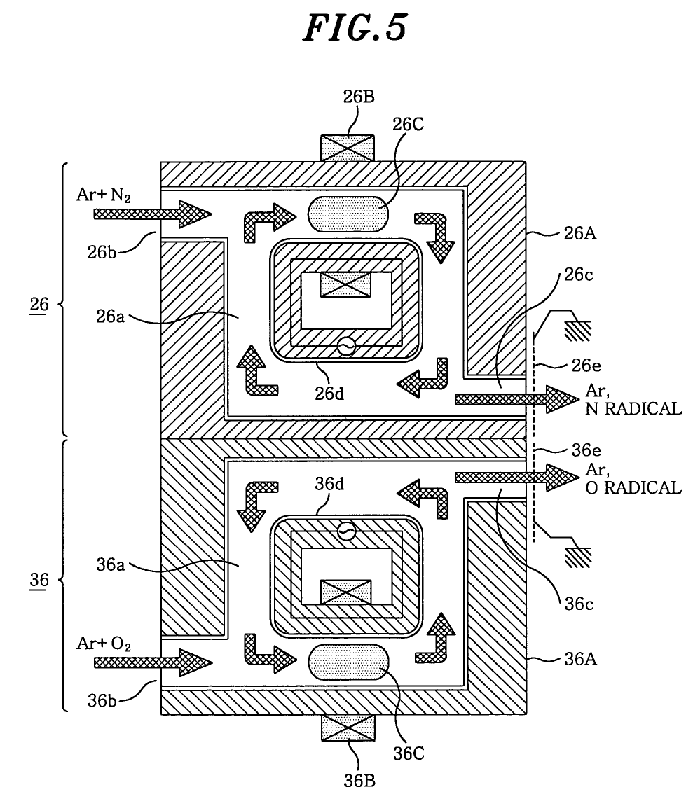

FIG. 5 shows configurations of the remote plasma sources 26 and 36 used for the substrate processing apparatus of FIG. 4. The remote plasma sources 26 and 36 are installed adjacent to each other on the processing vessel 21. For example, the remote plasma sources 26 and 36 are substantially plane symmetry with respect to an adjacent surface.

Referring to FIG. 5, first, the remote plasma source 26 contains a block 26A typically made of aluminum, in which a gas circulation passageway 26a, a gas inlet 26b and a gas outlet 26c connected thereto are formed, and a ferrite core 26B is formed in one portion of the block 26A.

Inner surfaces of the gas circulation passageway 26a, the gas inlet 26b and the gas outlet 26c are subject to a fluoropolymer coating 26d, and a plasma 26C is formed inside the gas circulation passageway 26a by supplying a high frequency (RF) power having a frequency of 400 kHz into a coil rolled to the ferrite core 26B.

Accompanied by an excitation of the plasma 26C, nitrogen radicals and nitrogen ions are formed in the gas circulation passageway 26a. However, the nitrogen ions having strong tendencies to move straightforward disappears when circulating the circulation passageway 26a, and the nitrogen radicals N₂* are mainly emitted from the gas outlet 26c. Further, in the configuration of FIG. 5, an ion filter 26e grounded to the gas outlet 26c is provided, so that charged particles as well as the nitrogen ions are removed and thus the nitrogen radicals are only supplied to the processing space 21B. Still further, even in case where the ion filter 26e is not grounded, the ion filter 26e serves as a diffusion plate, so that the charged particles as well as the nitrogen ions can be sufficiently removed. Still further, in case of performing a process requiring a large amount of N₂ radicals, the ion filter 26e may be detached to prevent extinction of the N₂ radicals due to a collision thereof in the ion filter 26e.

In the same manner, the remote plasma source 36 contains a block 36A typically made of aluminum, in which a gas circulation passageway 36a, a gas inlet 36b and a gas outlet 36c connected thereto are formed, and a ferrite core 36B is formed in one portion of the block 36A.

Inner surfaces of the gas circulation passageway 36a, the gas inlet 36b and the gas outlet 36c are subject to a fluoropolymer coating 36d, and a plasma 36C is formed in the gas circulation passageway 36a by supplying a high frequency (RF) power having a frequency of 400 kHz to a coil rolled to the ferrite core 36B.

Accompanied by an excitation of the plasma 36C, oxygen radicals and oxygen ions are formed inside the gas circulation passageway 36a. However, the oxygen ions having strong tendencies to move straightforward disappears when circulating the circulation passageway 36a, and the oxygen radicals O₂* are mainly emitted from the gas outlet 36c. Further, in the configuration of FIG. 5, an ion filter 36e grounded to the gas outlet 26c is provided, so that charged particles as well as the oxygen ions are removed and the oxygen radicals are only supplied to the processing space 21B. Still further, the ion filter 36e serves as a diffusion plate even in case where the ion filter 36e is not grounded, so that the charged particles as well as the oxygen ions can be sufficiently removed. Still further, in case of performing a process requiring a large amount of O₂ radicals, the ion filter 36e may be detached to prevent extinction of O₂ radicals due to a collision thereof in the ion filter 36e.

As described above, by separating the oxygen radical generation unit for producing the oxygen radicals from the nitrogen radical generation unit for producing the nitrogen radicals, the influence of the residual oxygen becomes weak in the nitridation processing, in case where the base oxide film is formed by oxidizing the silicon substrate of the substrate W to be processed and the oxynitride film is formed by nitriding the base oxide film.

For example, if the silicon substrate is subject to the oxidation by the oxygen radicals, and subsequently, subject to the nitridation by the nitrogen radicals in the same radical source, an oxygen or a product containing the oxygen used for the oxidation remains. As a result, the oxidation due to the residual oxygen is progressed in the nitridation process, resulting in a problem of the film growth of the oxide film.

In case of the present embodiment, it is possible to suppress the influence of the film growth phenomenon of the oxide film, which means that the oxidation of the silicon substrate is progressed in the nitridation processing due to the residual oxygen of the above-described radical generation unit. As a result, a film growth of the base oxide film 202 of FIG. 3 is small, so that an ideal base oxide film and an oxynitride film can be formed.

Further, in case where there is an influence of the residual oxygen as mentioned above, the oxidation may be facilitated to thereby generate the film growth, and the nitrogen concentration of the oxynitride film 202A may be lowered. However, in case of the substrate processing apparatus 20, the influence of the residual oxygen becomes reduced, the nitridation is progressed and the nitrogen concentration can be adjusted at a desired value.

Further, in case of the substrate processing apparatus 20 in accordance with the present invention, the radical generation mechanism of the remote plasma source 26 for producing the nitrogen radicals is the same as that of the remote plasma source 36 for producing the oxygen radicals, so that the radical source is separated and the structure is simplified. Thus, productivity of the substrate processing apparatus can be enhanced.

Next, as a second embodiment of the present invention, a method for forming the extremely thin base oxide film 202 which includes the oxynitride film 202A on the silicon substrate 201 of FIG. 3, by the substrate processing apparatus 20, will now be discussed with reference to the drawings.

### Second Embodiment

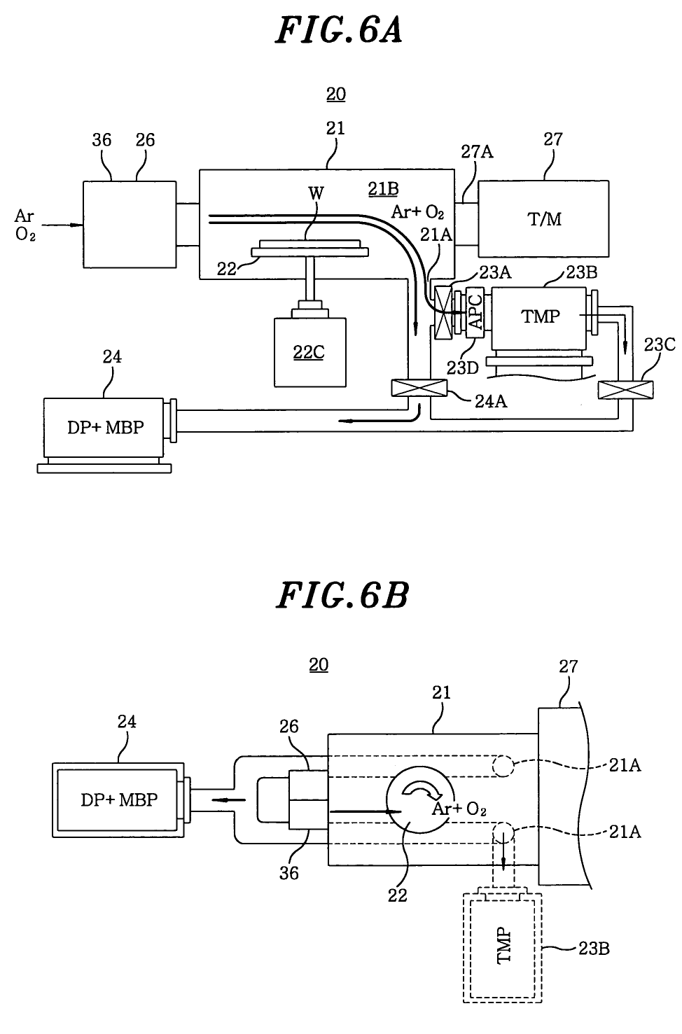

FIGS. 6A and 6B are of a side view and a plane view, respectively, showing a case of performing a radical oxidation of the substrate W to be processed by using the substrate processing apparatus 20 of FIG. 4.

Referring to FIGS. 6A and 6B, an Ar gas and an oxygen gas are supplied into the remote plasma radical source 36, and a plasma is excited at a high frequency of several 100 kHz to form oxygen radicals. The formed oxygen radicals flow along the surface of the substrate W to be processed and is discharged through the gas exhaust port 21A and the pump 24. As a result, the processing space 21B is set at a process pressure in the range from 1.33 Pa to 1.33 kPa (0.01 to 10 Torr) appropriate for the radical oxidation of the substrate W. Specifically, it is preferable that the pressure is in the range from 6.65 Pa to 133 Pa (0.05 to 1.0 Torr). The oxygen radicals formed above oxidize the surface of the rotating substrate W to be processed when flowing along the surface of the substrate W to be processed, so that an extremely thin oxide film having a film thickness of 1 nm or less, particularly about 0.4 nm equivalent to 2˜3 atomic layers, can be formed stably and reproducibly on the surface of the silicon substrate of the substrate W to be processed.

In the oxidation process of FIGS. 6A and 6B, a purge process may be carried out prior to the oxidation process. In the purge process, the valves 23A and 23C are opened and the valve 24A is closed, so that the pressure of the processing space 21B is depressurized to a pressure of 1.33×10⁻¹ to 1.33×10⁻⁴ Pa and, moisture and the like remaining in the processing space 21B are purged.

Further, in the oxidation process, two cases are considered as a gas exhaust path: a case of passing the turbo molecular pump 23B; and a case of not passing it.

In case where the valves 23A and 23C are closed, the valve 24A is opened and only the dry pump 24 is used without using the turbo molecular pump 23B. In this case, there are merits that a region where the residual moisture and the like are attached on purging becomes small, and the residual gas is easily discharged since the pumping rate of the pump is high.

Further, there is a case that the valves 23A and 23C are opened and the valve 24A is closed to use the turbo molecular pump 23B as the gas exhaust path. In this case, since the vacuum level inside the processing vessel can be raised by using the turbo molecular pump, the partial pressure of the residual gas can be reduced.

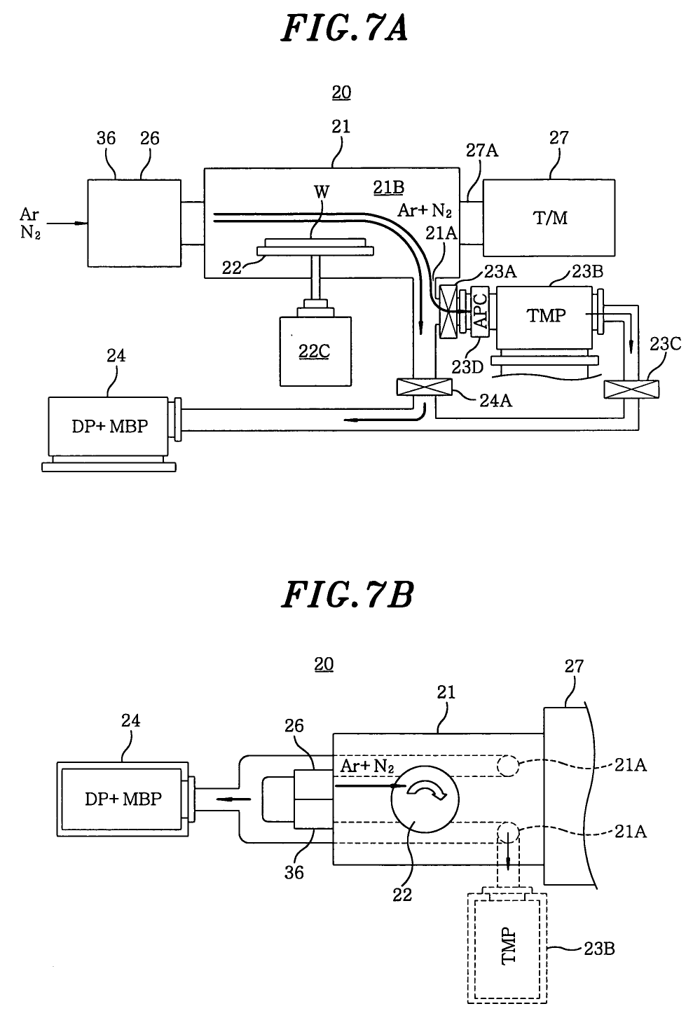

As described above, by using the substrate processing apparatus 20 of FIG. 4, it is possible to form the extremely thin oxide film on the surface of the substrate W to be processed, and to nitride the surface of the oxide film, as will be explained below in FIGS. 7A and 7B.

### Third Embodiment

FIGS. 7A and 7B correspond to a third embodiment of the present invention, and are of a side view and a plane view, respectively, showing a case of performing a radical nitridation on the substrate W to be processed by using the substrate processing apparatus 20 of FIG. 4.

Referring to FIGS. 7A and 7B, an Ar gas and a nitrogen gas are supplied into the remote plasma radical source 26, and a plasma of a high frequency of several 100 kHz is excited to form nitrogen radicals. The formed nitrogen radicals flow along the surface of the substrate W to be processed and is discharged through the gas exhaust port 21A and the pump 24. As a result, the processing space 21B is set at a process pressure in the range from 1.33 Pa to 1.33 kPa (0.01 to 10 Torr) appropriate for a radical nitridation of the substrate W. Specifically, it is preferable that the pressure is in the range from 6.65 Pa to 133 Pa (0.05 to 1.0 Torr). The nitrogen radicals formed above nitride the surface of the rotating substrate W to be processed while it flows along the surface of the substrate W to be processed.

In the nitridation process of FIGS. 7A and 7B, a purge process may be carried out prior to the nitridation process. In the purge process, the valves 23A and 23C are opened and the valve 24A is closed, so that the pressure of the processing space 21B is depressurized to a pressure in the range from 1.33×10⁻¹ to 1.33×10⁻⁴ Pa and, moisture and the like remaining in the processing space 21B are purged.

In the nitridation process, two cases are considered as a gas exhaust path, as well: a case of passing the turbo molecular pump 23B; and a case of not passing it.

In case where the valves 23A and 23C are closed, the valve 24A is opened and only the dry pump 24 is used without using the turbo molecular pump 23B. In this case, there are merits that a region where the residual moisture and the like are attached on purging becomes small, and the residual gas is easily discharged since the pumping rate of the pump is high.

Further, there is a case that the valves 23A and 23C are opened and the valve 24A is closed to use the turbo molecular pump 23B as the gas exhaust path. In this case, since the vacuum level inside the processing vessel can be raised by using the turbo molecular pump, the partial pressure of the residual gas can be reduced.

As described above, by using the substrate processing apparatus 20 of FIG. 4, it is possible to form the extremely thin oxide film on the surface of the substrate W to be processed, and to nitride the surface of the oxide film.

### Fourth Embodiment

Meanwhile, in the nitridation processing of the oxide film on the substrate W to be processed, the nitrogen radicals formed by the remote plasma source 26 are supplied from the gas outlet 26c to an inside of the processing vessel 21, i.e., the processing space 21B, and flows along the surface of the substrate W to be processed to thereby form a nitrogen radical flow path towards the gas exhaust port 21A.

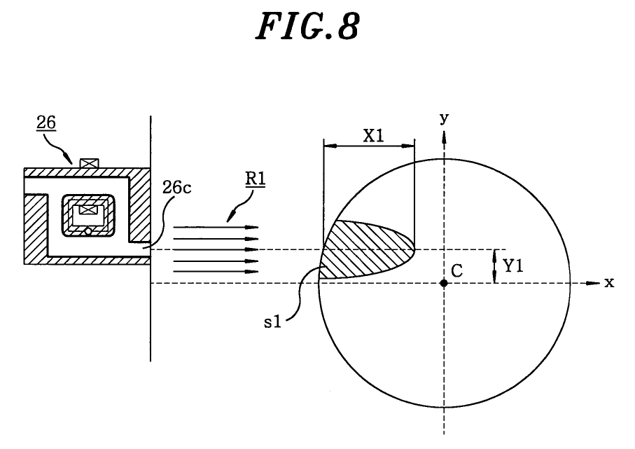

As a fourth embodiment of the present invention, FIG. 8 typically shows a forming shape of the nitrogen radical flow path as mentioned above. In the drawing, identical reference numerals will be assigned for corresponding parts having substantially the same functions and configurations, and superfluous explanations will be omitted.

FIG. 8 schematically describes a relationship between the remote plasma source 26 and the position of the substrate W to be processed together with a nitrogen radical flow path R1 formed by the nitrogen radicals supplied from the gas outlet 26c and the resultant radical distribution formed on the substrate W to be processed.

Referring to FIG. 8, the nitrogen radicals supplied from the gas outlet 26c form the nitrogen radical flow path R1 from the corresponding gas outlet 26c to the gas exhaust port 21A. Wherein, it is configured such that the center of the substrate W to be processed coincides with a center of the wafer. Further, with respect to an x-axis and a y-axis passing and running through the center C of the wafer, the x-axis is set to run from a first side of the processing vessel 21, in which the remote plasma source 26 is installed, toward a second side of the processing vessel 21, in which the gas exhaust port 21A is provided, and the y-axis is set to be normal to this.

Further, a region S1 indicates a range where the oxide film on the substrate W to be processed is nitrided by the nitrogen radical flow path R1. In this case, the substrate W to be processed is configured not to rotate.

In this case, it is considered that a length X1 in the direction of the x-axis in the region S1 depends on a flow rate of the nitrogen radicals, i.e., substantially depends on a flow rate of a nitrogen introduced into the remote plasma source 26.

Further, given that Y1 is a distance between the center of the nitrogen radical flow path R1 and the center C of the wafer, it is considered that the film thickness variance σ of the oxynitride film of the substrate W to be processed depends on the distances X1 and Y1, in case of rotating the substrate W to be processed.

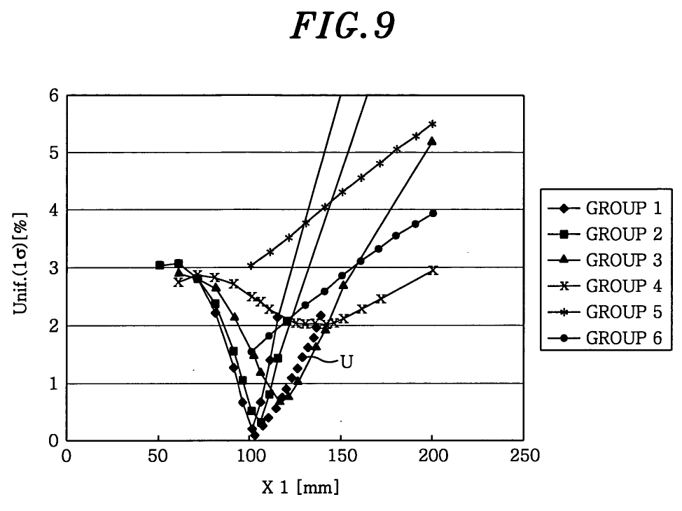

Subsequently, calculation results of the film thickness variance σ of the oxynitride film in case of varying the distances X1 and Y1 will be described in FIG. 9. FIG. 9 corresponds to a case where a 300 mm silicon wafer is used as a substrate to be processed.

Referring to FIG. 9, a horizontal axis indicates the distance X1, and a vertical axis indicates the film thickness variance σ of the oxynitride film. Wherein, group 1 exhibits a case of the distance Y1=0 mm, and in the same manner, group 2, group 3, group 4, group 5, and group 6 indicate cases of the distance Y1=20 mm, 40 mm, 60 mm, 100 mm, and 150 mm, respectively.

First, in case where the distance Y1 is 0, i.e., the center of the nitrogen radical flow path R1 passes through the center C of the wafer, and the distance X1 is 100 mm, variance σ is a minimum and the film thickness distribution of the oxynitride film is excellent.

Next, in case of varying the X1 value for the respective Y1 values, a curve formed by linking minimum values of variance σ is shown as U in the drawing. As the distance Y1 becomes large, the distance X1 where variance σ becomes minimum tends to increase. Further, in case where the distance Y1 is 100 mm or 150 mm, the center of the radical path R1 is considerably away from the center C of the wafer, so that it is not preferable. Further, variance σ becomes extremely large.

For example, in case where the oxide film and the oxynitride film formed by the substrate processing apparatus 20 are used for the base oxide film 202 and the oxynitride film 202A of the semiconductor device 200, if variance σ is 1% or less, the film thickness distribution of the oxynitride film is excellent and it can be applied for the fabrication of the semiconductor device.

Seeing FIG. 9, it may be considered that there is a value of the distance X1 where σ becomes 1% or less in case of the distance Y1 of 40 mm or less, and a good film thickness distribution of the oxynitride film can be obtained.

As described above, the film thickness distribution of the oxynitride film largely depends on a forming method of the nitrogen radical flow path R1, i.e., an install method of the remote plasma source 26 related to the formation of the nitrogen radical flow path R1. As mentioned above, the remote plasma source 26 may be installed ideally such that the nitrogen radical flow path R1 passes through the center of the substrate W to be processed.

However, taking into consideration the oxidation processing of the substrate W to be processed using the remote plasma source 36, the installation place of the remote plasma source 36 may be interfered with that of the remote plasma source 26 due to the following reason.

A region to be oxidized by an oxygen radical flow path R2 along the substrate W to be processed shows the same trend with the region S1, wherein the oxygen radical flow path R2 is formed by the oxygen radicals from the gas outlet 36c of the remote plasma source 36 towards the gas exhaust port 21A. Accordingly, the install place of the remote plasma source 36 where the film thickness distribution of the formed oxide film becomes best is on the x-axis. If it is intended to install the remote plasma source 26 on the x-axis, it is interfered with the remote plasma source 36.

Therefore, the remote plasma sources 26 and 36 need to be installed such that they do not interfere with each other and the film thickness distributions of the formed oxide film and the oxynitride film become better.

### Fifth Embodiment

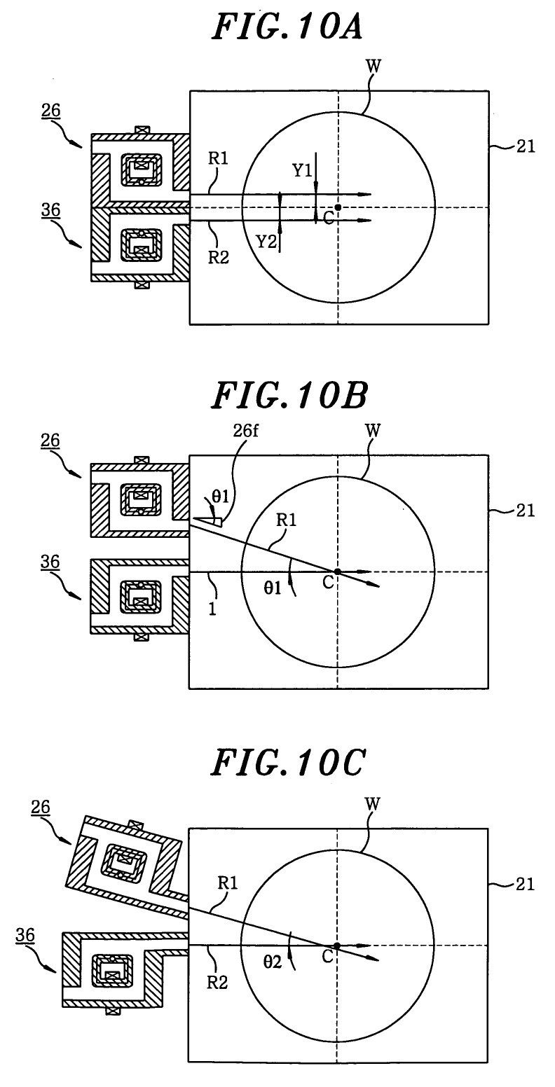

FIGS. 10A, 10B, and 10C correspond to a fifth embodiment and are views showing install methods for installing the remote plasma sources 26 and 36 to the processing vessel 21. In the drawing, identical reference numerals will be assigned for corresponding parts having substantially the same functions and configurations, and superfluous explanations will be omitted.

First, referring to FIG. 10A, the remote plasma sources 26 and 36 are disposed adjacent to each other, and the nitrogen radical flow path R1 and the oxygen radical flow path R2 are installed with parallel to each other in the processing vessel 21.

In this case, as mentioned above, the film thickness distribution becomes better as Y1 gets smaller, so that Y1, i.e., an offset amount of the remote plasma source 26 from the x-axis, is made to be as small as possible, e.g., 40 mm or less, whereby the film thickness variance σ of the oxynitride film can be 1% or less.

Further, in the same manner, the film thickness distribution becomes better as the distance Y2 between the center of the oxygen radical flow path R2 and the center C of the wafer gets smaller, so that if a value of Y2, i.e., an offset amount of the remote plasma source 36 from the x-axis, is made to be as small as possible, e.g., 40 mm or less, it is expected that the film thickness variance value σ2 of the oxide film can be 1% or less.

Subsequently, in case referred to FIG. 10B, it is configured such that the remote plasma source 36 is installed on the x-axis and the center of the oxygen radical flow path R2 is installed to pass through the center C of the wafer, for example. While the remote plasma source 26 is installed apart from the remote plasma source 36, the center of the nitrogen radical flow path R1 is configured to pass through the center C of the wafer, as shown below.

In the vicinity of the gas outlet 26c of the remote plasma source 26, a gas flow adjusting plate 26f is installed to be used for changing the direction of the nitrogen radical flow path R1. Namely, the nitrogen radical flow path R1 to be supplied from the gas outlet 26c is made to hit the gas flow adjusting plate 26f and flow thereafter along the gas flow adjusting plate 26f that is forming an angle, e.g., θ1 with respect to the x-axis shown in the drawing, so that the center of the nitrogen radical flow path R1 whose direction has been changed is configured to pass through the center C of the wafer.

In this case, since the centers of the nitrogen radical flow path R1 and the oxygen radical flow path R2 pass through the center C of the wafer, the film thickness distributions of the oxide film and oxynitride film formed on the substrate W to be processed become better.

Further, the remote plasma sources 26 and 36 can be installed apart from each other, so that flexibility of design or layout is increased, and by using the flow adjusting plate angled with θ1 whose value can be changed, the remote plasma source 26 can be installed at various positions.

Still further, it may be possible that the remote plasma source 26 is installed on the x-axis and the flow adjusting plate is installed in the vicinity of the gas outlet 36c of the remote plasma source 36. In this case, the centers of the nitrogen radical flow path R1 and the oxygen radical flow path R2 pass through the center C of the wafer as well, so that the respective film thickness distributions of the oxide and oxynitride films formed on the substrate W to be processed can be better.

In addition, it may be possible that the remote plasma sources 26 and 36 are disposed apart from the x-axis and the flow adjusting plates are installed in the vicinity of the gas outlets 26c and 36c. In this case, the centers of the nitrogen radical flow path R1 and the oxygen radical flow path R2 can be made to pass through the center C of the wafer and the respective film thickness distributions of the oxide and oxynitride films formed on the substrate W to be processed can be improved.

By doing this, flexibility of design or layout is further increased, and by using two flow adjusting plates angled with θ1 that can be varied, the remote plasma sources 26 and 36 can be installed at various positions.

Further, the flow adjusting plate can be installed inside the remote plasma source, i.e., in an inner side of the gas outlet. In this case, it is unnecessary to secure an install place for the flow adjusting plate inside the processing vessel 21.

Still further, as an example of a method changing the direction of the nitrogen radical flow path R1, a method shown in FIG. 10C may be adopted.

Referring to FIG. 10C, in the present drawing, the remote plasma source 36 is installed on the x-axis and the center of the oxygen radical flow path R2 is installed to pass through the center C of the wafer, for example, same as in FIG. 10B. While the remote plasma source 26 is installed apart from the remote plasma source 36, the center of the nitrogen radical flow path R1 is configured to pass through the center C of the wafer, as shown below.

In this case, the remote plasma source 26 is installed to be sloped with respect to the x-axis such that the nitrogen radical flow path R1 makes an angle, e.g., θ2, to the x-axis, and it is configured such that the center of the nitrogen radical flow path R1 passes through the center C of the wafer.

Since the centers of the nitrogen radical flow path R1 and the oxygen radical flow path R2 pass through the center C of the wafer, the respective film thickness distributions of the oxide and oxynitride films formed on the substrate W to be processed become better.

Further, the remote plasma sources 26 and 36 can be installed apart from each other, so that flexibility of design or layout is increased, and by changing the angle θ2, the install place of remote plasma source 26 can be changed to various positions.

Still further, it may be possible that the remote plasma source 26 is installed on the x-axis and the remote plasma source 36 is installed to be sloped relative to the x-axis. In the same manner, in this case, the centers of the nitrogen radical flow path R1 and the oxygen radical flow path R2 can be made to pass through the center C of the wafer, so that the respective film thickness distributions of the oxide and oxynitride films formed on the substrate W to be processed can be made better.

In addition, it can be configured such that the remote plasma sources 26 and 36 are disposed away from the x-axis, and installed to be sloped with respect to the x-axis, respectively. In the same manner, the centers of the nitrogen radical flow path R1 and the oxygen radical flow path R2 can be made to pass through the center C of the wafer, so that the respective film thickness distributions of the oxide and oxynitride films formed on the substrate W to be processed can be made better.

By doing this, flexibility of design or layout is further increased, and by changing the angle θ2, the install places of remote plasma sources 26 and 36 can be changed at various positions, respectively.

Further, in case where the direction of the nitrogen radical flow path R1 or the oxygen radical flow path R2 is changed by the methods shown in FIGS. 10B and 10C, the case where the R1 or the R2, after changing its direction, passes through the center C of wafer is the optimum case for the respective film thickness distributions of the oxynitride and the oxide film. However, if a distance between the R1 or the R2 and the center C of the wafer is equal to or less than 40 mm, it is considered that variance σ of the oxynitride film or the oxide film can be assured to be equal to or less than 1%.

Still further, the methods of installing the flow adjusting plate described in FIG. 10B and installing the remote plasma source to be sloped to the x-axis as shown in FIG. 10C may be combined to be performed. In this case, by installing the remote plasma sources 26 and 36 at various places, it is possible to improve the respective film thickness distributions of the oxide and the oxynitride film formed on the substrate W to be processed.

### Sixth Embodiment

Next, a sixth embodiment of the present invention will be discussed. As mentioned above, in case where the oxide film is formed by oxidizing the silicon substrate in the processing vessel and the oxynitride film is formed by nitriding the oxide film in the corresponding processing vessel, an oxidation reaction may occur at the time of the nitridation process due to the influence of oxygen and the residues containing oxygen, which have been used for the oxidation processing, to thereby grow the oxide film. As described above, if the oxide film grows during the oxynitride processing, the effect of using the high-K gate insulating film described in FIG. 3 is cancelled.

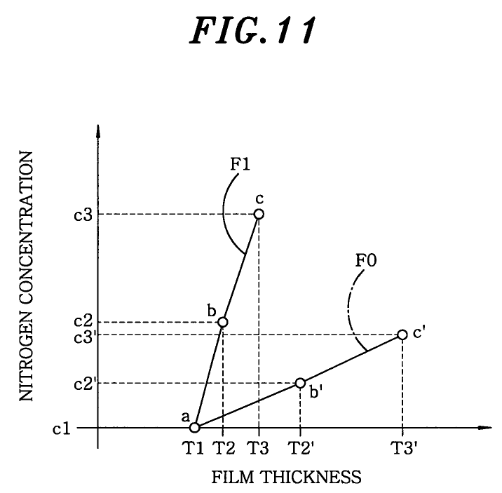

Thus, when forming the base oxide film of the high-K gate insulating film and the oxynitride film on the corresponding oxide film, it is important to eliminate the influence of the film growth of the base oxide film during carrying out the nitridation. There will be shown examples of models for strong and weak influences of the residual oxygen when forming the oxynitride film as described above in FIG. 11. In the graph of FIG. 11, the horizontal axis represents a total film thickness of the oxide and the oxynitride film formed on the silicon substrate, and the vertical axis represents a nitrogen concentration of the formed oxynitride film.

First, there will be described in the following for a case where there is a strong influence of the residual oxygen, i.e., the case of F0 shown in the drawing. On the line of F0, it is given that a is a time of forming the base oxide film on the silicon substrate, T1 is a film thickness at a and C1 is a nitrogen concentration. In this case, the nitrogen concentration is a value below the measurement limitation since the nitridation process is not performed yet.

Subsequently, b′ represents a state where the oxynitride film is formed on the base oxide film by nitriding the base oxide film. T2′ is the film thickness at b′ and C2′ is the nitrogen concentration. Further, c′ represents a state where the nitridation is progressed from the state of b′, wherein the film thickness is T3′ and the nitrogen concentration is C3′.

As described above, the nitrogen concentration is increased by nitriding the oxide film in case of F0, and it is expected that the increase in the film thickness, e.g., a value of T3′-T1, becomes large compared to the case where there is a weak influence of the residual oxygen that will be discussed later. Further, it is expected that the increase in the nitrogen concentration becomes small compared to the case where there is a weak influence of the residual oxygen that will be discussed later.

Next, in case where there is a weak influence of the residual oxygen, i.e., in case of F1 shown in the drawing, it is given that a is a time of forming the base oxide film on the silicon substrate, b represents a nitrided state and c represent a state where the nitridation is further progressed from b, in the same manner. In the case of F1, the increase of the film thickness at b state is small, and it is expected that the increase in the film thickness, i.e., a value of T3-T1, at a state where the nitridation is further progressed to the c state is small compared with the case of F0.

Further, the nitrogen concentrations C2 and C3 are higher than C2′ and C3′. In the case of F1, the influence of the residual oxygen inside the processing vessel is not strong, so that the oxidation of the silicon substrate due to the residual oxygen may not be facilitated in the nitridation process, whereby the nitridation can be easily progressed and the oxynitride film having a high nitrogen concentration can be formed.

Namely, by eliminating the influence of the residual oxygen inside the processing vessel, it is possible to form the oxynitride film having a desired value on the base oxide film, while securing a thickness, e.g., about 0.4 nm or less, which is preferable as a base oxide film of a gate oxide film of the high-K gate insulating film.

For example, in case of the substrate processing apparatus 20, the radical source forming the oxygen radicals used at the oxidation is separated from the radical source forming the nitrogen radicals used at the nitridation. However, the influence of the oxygen and the residues containing the oxygen, which are used when forming the oxygen radicals, cannot be completely excluded.

Next, a method for suppressing the influence of the residual oxygen will be discussed in detail.

### Seventh Embodiment

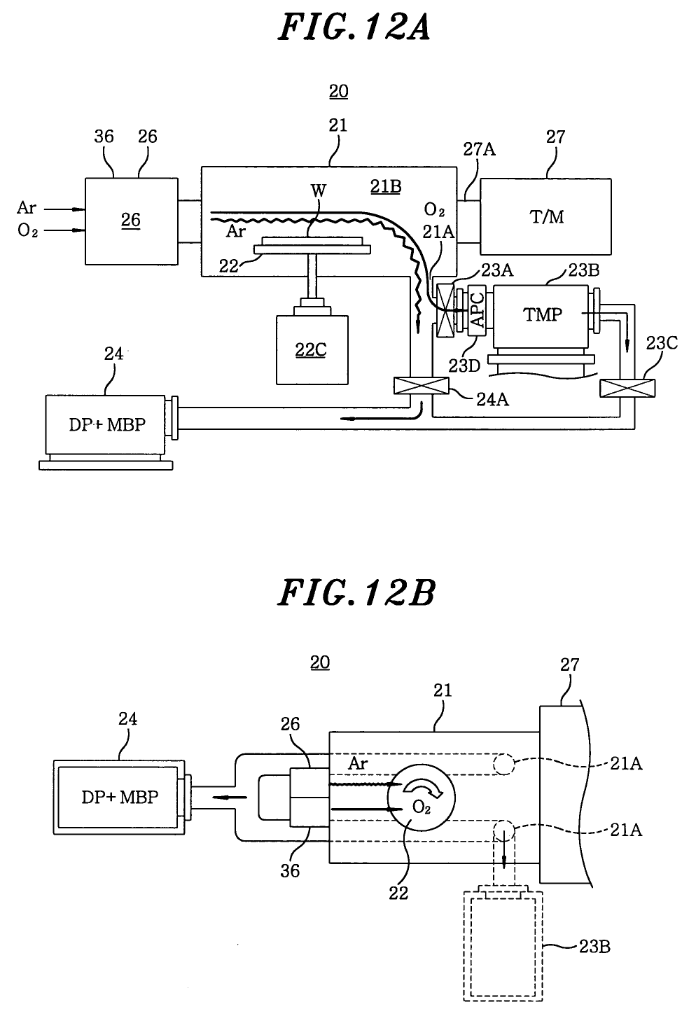

FIGS. 12A and 12B correspond to a seventh embodiment and are of a side view and a plane view showing a method for performing a radical oxidation on the substrate W to be processed by using the substrate processing apparatus 20 of FIG. 4. In the drawing, identical reference numerals will be assigned for corresponding parts having substantially the same functions and configurations, and superfluous explanations will be omitted. In case of the present embodiment, it is characterized in that the influence of the residual oxygen is weak and the film growth of the base oxide film is small in the nitridation process after the oxidation process shown in the drawing.

In the drawing, the base oxide film is formed by oxidizing the silicon substrate, same as the case shown in FIGS. 6A and 6B. The different thing from the case described in FIGS. 6A and 6B is that when the oxygen radicals are supplied into the processing space 21B from the remote plasma radical source 36, a purge gas, e.g., Ar or the like, is simultaneously supplied into the processing space 21B from remote plasma radical source 26. Except that the purge gas is supplied, it is the same as the case of FIGS. 6A and 6B.

As described above, since the oxygen radicals are used in the process of forming the base oxide film by oxidizing the silicon substrate, the oxygen radicals are supplied into the processing space 21B from the remote plasma source 36 as mentioned above. At this time, the oxygen radicals or the by-products containing oxygen, e.g., H₂O or the like, may flow backward from the gas outlet 26c of the remote plasma source 26.

As mentioned above, if the oxygen radicals or the by-products containing the oxygen flows backward, such a problem as the film growth of the base oxide film or the lowering of the nitrogen concentration may be caused in the nitridation processing shown in FIGS. 7A and 7B, for example.

Therefore, in the present embodiment, the purge gas is introduced into the processing space 21B from the remote plasma source 26 to prevent the oxygen or the by-product containing the oxygen from flowing backward to the remote radical source 26.

Further, for removing the oxygen or the by-product containing the oxygen flowing backward to the remote plasma source 26 as mentioned above, there is a method for performing, e.g., a vacuum purge or a gas purge by an inactive gas.

For example, the vacuum purge is a method of removing the oxygen or the by-product containing the oxygen remaining in the processing space 21B or the remote plasma source 26 by exhausting the processing space to a low pressure (a high vacuum) state after terminating the oxidation process.

In the same manner, the gas purge is a method of removing the oxygen remaining in the processing space 21B or the remote plasma source 26 by introducing the inactive gas into the processing space 21B after terminating the oxidation process.

Generally, the vacuum purge and the gas purge are combined to be performed several times. However, if the vacuum purge and the gas purge are performed, the processing time is required, resulting in a problem that throughput of the substrate processing apparatus 20 is reduced and productivity is lowered. Further, since the expensive exhaust means having a high exhaust velocity of, e.g., a turbo molecular pump or the like, is needed, there is a problem of cost increase for the apparatus.

In the present embodiment, it is possible to eliminate the influence of the residual oxygen as mentioned above, without lowering throughput of the apparatus.

Further, after the oxidation processing shown in FIGS. 12A and 12B, the nitridation process is performed to nitride the base oxide film, and to thereby form the oxynitride film. At that time, since the influence of a back flow of the oxygen to the remote plasma source 26 is eliminated as mentioned above, such a phenomenon in which the oxidation due to the residual oxygen or the product containing the oxygen is progressed to thereby grow the base oxide film is suppressed. Hence, the nitridation is progressed, and the oxynitride film having a desired nitrogen concentration can be formed.

As a result, it is possible to form the extremely thin base oxide film of, e.g., about 0.4 nm, appropriate to be used in the semiconductor device 200 described in FIG. 3, and to form the oxynitride film 202A having a proper concentration on the base oxide film.

Further, the purge gas used in the present embodiment may be any inactive gas, and nitrogen, helium, or the like as well as the above-described Ar gas can be used.

Still further, a method for reducing the influence of the residual oxide by using the purge gas in the oxidation process when forming the base oxide film may be performed in another device. For example, it can be carried out in the radical source for generating the oxygen radicals and in the substrate processing apparatus 20A to be explained below, on which an ultraviolet light source is mounted.

### Eighth Embodiment

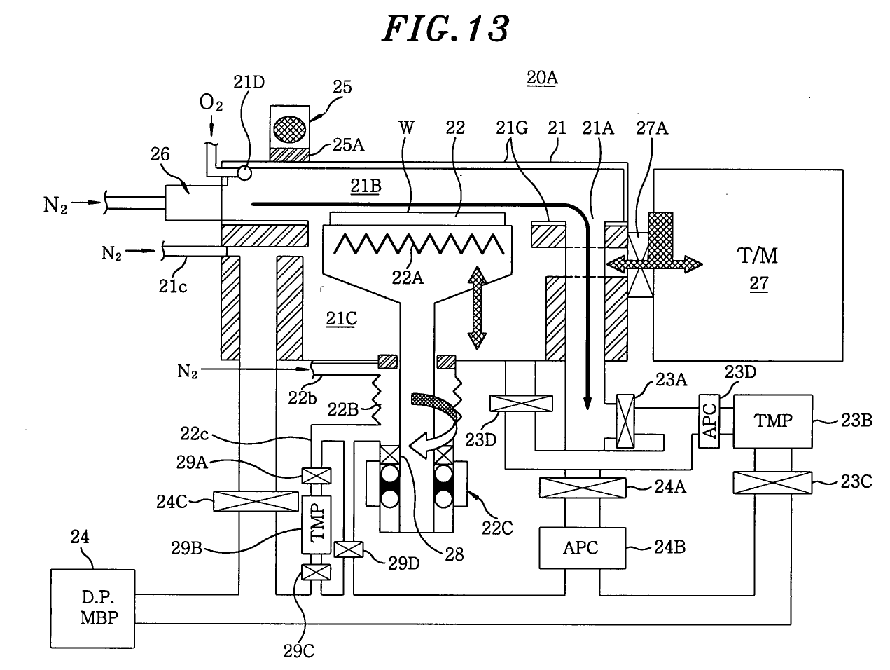

FIG. 13 corresponds to an eighth embodiment of the present invention, and shows a schematic configuration of a substrate processing apparatus 20A for forming an extremely thin base oxide film 202 including an oxynitride film 202A on the silicon substrate 201 of FIG. 3. In the drawing, identical reference numerals will be assigned for corresponding parts having substantially the same functions and configurations, and superfluous explanations will be omitted.

Referring to FIG. 13, the case of the substrate processing apparatus 20A shown in the present drawing is different from that of the substrate processing apparatus 20 described in FIG. 4 in that a processing gas supply nozzle 21D supplying the oxygen gas is provided to a side facing the gas exhaust port 21A in the processing vessel 21, while having the substrate W to be processed therebetween, and the oxygen gas supplied to the processing gas supply nozzle 21D is configured to flow along the surface of the substrate W to be processed in the processing space 21B to thereby be discharged through the gas exhaust port 21A.

Further, an ultraviolet light source 25 having a quartz window 25A is provided on the processing vessel 21 at a place corresponding to a region between the processing gas supply nozzle 21D and the substrate W to be processed, in order to generate the oxygen radicals by activating the processing gas supplied from the processing gas supply nozzle 21D as mentioned above. Namely, the oxygen gas introduced into the processing space 21B from the processing gas supply nozzle 21D is activated by driving the ultraviolet light source 25, and the resultant oxygen radicals flow along the surface of the substrate W to be processed. By this, it can be formed on the surface of the rotating substrate W to be processed a radical oxide film having a film thickness of 1 nm or less, specifically, about 0.4 nm, a thickness equivalent to 2˜3 atomic layers.

Still further, the remote plasma source 26 is formed in an opposite side of the gas exhaust port 21A with respect to the substrate W to be processed. Accordingly, by supplying the nitrogen gas into the remote plasma source 26 together with the inactive gas such as Ar and the like and activating them by the plasma, it is possible to form the nitrogen radicals. The nitrogen radicals formed as described above flow along the surface of the substrate W to be processed and nitrifies the surface of the rotating substrate to be processed.

Still further, in the substrate processing apparatus 20A, the remote plasma source 36 is not installed, unlike in the substrate processing apparatus 20, since the ultraviolet light source 25 is used for generating the oxygen radicals.

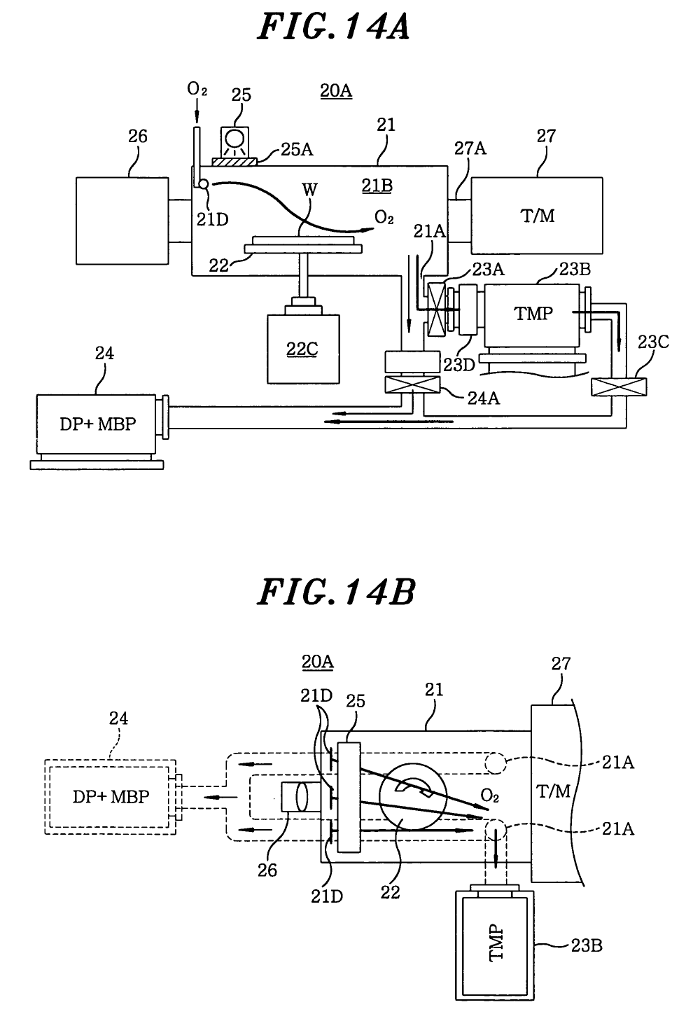

FIGS. 14A and 14B are of a side view and a plane view, respectively, showing a case where a radical oxidation is carried out on the substrate W to be processed by using the substrate processing apparatus 20A of FIG. 13, by the conventional method.

Referring to FIG. 14A, the oxygen gas is supplied into the processing space 21B from the processing gas supply nozzle 21D, flows along the surface of the substrate W to be processed, and then is discharged. Two cases are considered as a gas exhaust path: a case of passing the turbo molecular pump 23B; and a case of not passing it.

In case where the valves 23A and 23C are closed, the valve 24A is opened and only the dry pump 24 is used without using the turbo molecular pump 23B. In this case, there are merits that a region where the residual moisture and the like are attached becomes small and the gas is easily exhausted out since the pumping rate of the pump is high.

Further, there is a case that the valves 23A and 23C are opened and the valve 24A is closed to use the turbo molecular pump 23B as a gas exhaust path. In this case, the vacuum level inside the processing vessel can be raised by using the turbo molecular pump, so that the partial pressure of the residual gas can be lowered.

At the same time, the oxygen radicals are formed in an oxygen gas stream by driving the ultraviolet light source 25 generating an ultraviolet light having a wavelength of, preferably 172 nm. The formed oxygen radicals oxidize the surface of the rotating substrate when flowing along the surface of the substrate W to be processed. Through the oxidation by the ultraviolet excitation oxygen radical of the substrate W to be processed as described above (hereinafter, an UV-O₂ treatment), an extremely thin oxide film having a film thickness of 1 nm or less, particularly about 0.4 nm, equivalent to 2˜3 atomic layers can be formed stably and reproducibly on the surface of the silicon substrate.

FIG. 14B shows a plain view of the configuration of FIG. 14A.

Referring to FIG. 14B, it can be noted that the ultraviolet light source 25 is of a tube shaped light source extending in the intersection direction of oxygen gas stream, and the processing space 21B is exhausted through the gas exhaust port 21A by the turbo molecular pump 23B. Meanwhile, the gas exhaust path shown as a dotted line in FIG. 14B, which arrives at the pump 24 directly from the gas exhaust port 21A, is made by closing the valves 23A and 23C.

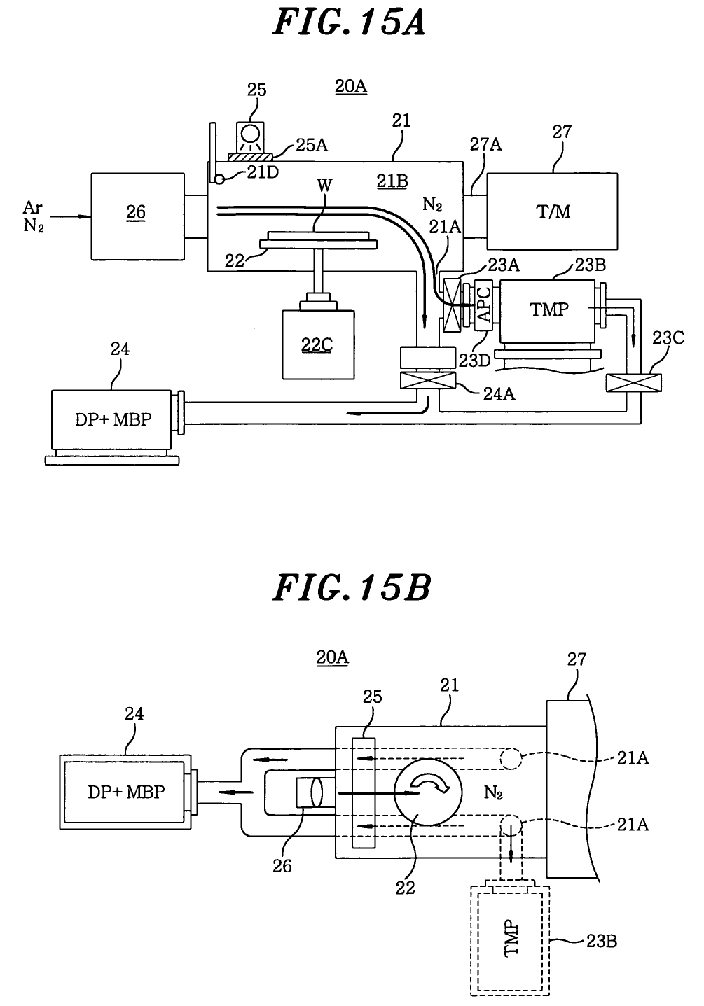

Subsequently, FIGS. 15A and 15B are of a side view and a plane view, respectively, showing a case where a radical nitridation (an RF-N₂ treatment) is carried out on the substrate W to be processed by using the substrate processing apparatus 20A of FIG. 13.

Referring to FIGS. 15A and 15B, the Ar gas and the nitrogen gas are supplied into the remote plasma radical source 26, and the nitrogen radicals are formed by exciting the plasma with a high frequency of several 100 kHz. The formed nitrogen radicals flow along the surface of the substrate W to be processed, and is discharged through the gas exhaust port 21A and the pump 24. As a result, the processing space 21B is set at a process pressure appropriate for the radical nitridation of the substrate W to be processed, i.e., in the range from 1.33 Pa to 1.33 kPa (0.01 to 10 Torr). Particularly, it is preferable to use in the range from 6.65 to 133 Pa (0.05 to 1.0 Torr). The nitrogen radicals formed above nitride the surface of the rotating substrate W to be processed when flowing along the surface of the substrate W to be processed.

In the nitridation processing of FIGS. 15A and 15B, a purge process may be performed prior to the nitridation processing. In the purge process, the valves 23A and 23C are opened and the valve 24A is closed, so that the pressure of the processing space 21B is reduced to a pressure of 1.33×10⁻¹ to 1.33×10⁻⁴ Pa and the oxygen or the moisture remaining in the processing space 21B is purged. In the nitridation process, two cases are considered as a gas exhaust path, as well: a case of passing the turbo molecular pump 23B and a case of not passing it.

In case where the valves 23A and 23C are closed, the valve 24A is opened and only the dry pump 24 is used while the turbo molecular pump 23B is not used. In this case, there are merits that a region where the residual moisture and the like are attached when purging becomes small and the residual gas is easily discharged since the pumping rate of the pump is large.

Further, there is a case that the valves 23A and 23C are opened and the valve 24A is closed to use the turbo molecular pump 23B as the gas exhaust path. In this case, since the vacuum level inside the processing vessel can be raised by using the turbo molecular pump, the partial pressure of the residual gas can be reduced.

As described above, by using the substrate processing apparatus 20A of FIG. 13, the extremely thin oxide film can be formed on the surface of the substrate W to be processed, and the surface of the oxide film can be nitrided.

By using the substrate processing apparatus 20A, a method for suppressing the influence of the residual oxygen by using the purge gas mentioned in the prior embodiment will be now discussed below.

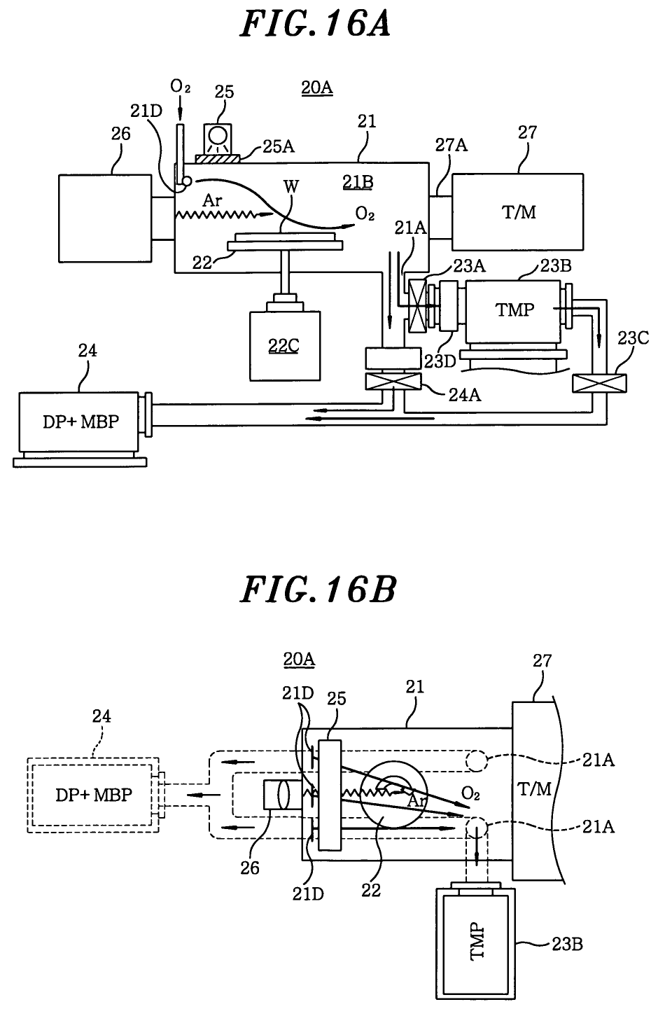

FIGS. 16A and 16B are of a side view and a plane view, respectively, showing a method for performing a radical oxidation on the substrate W to be processed in accordance with the eighth embodiment of the present invention, by using the substrate processing apparatus of FIG. 13. In the drawing, identical reference numerals will be assigned for corresponding parts having substantially the same functions and configurations, and superfluous explanations will be omitted. The present embodiment is a method that the influence of the residual oxygen is not strong and the film growth of the base oxide film is small in the nitridation processing after the oxidation processing shown in the drawing.

Referring to FIGS. 16A and 16B, in case of the present embodiment, the oxidation is performed on the surface of the substrate W to be processed same as in the case described in FIGS. 14A and 14B. However, it is different from the case described in FIGS. 14A and 14B in that when the processing gas, e.g., the oxygen or the like, for forming the oxygen radicals is supplied into the processing space 21B from the processing gas supply nozzle 21D, a purge gas, e.g., Ar or the like, is supplied into the processing space 21B from remote plasma radical source 26. Except that the purge gas is supplied, it is the same as the case of FIGS. 14A and 14B.

As described above, the oxygen radicals are employed in the process of oxidizing the silicon substrate, so that the processing gas supplied from the gas supply nozzle 21D is activated and thus the oxygen radicals are formed in the processing space 21B. At that time, the oxygen radicals or the products containing the oxygen may flow backward to thereby enter therein.

As described above, if the oxygen radicals or the products containing the oxygen flows backward, such a problem as the film growth of the base oxide film or the lowering of the nitrogen concentration may be caused, in the nitridation processing shown in FIGS. 15A and 15B, for example.

Accordingly, in the present embodiment, the purge gas is introduced from the remote plasma source 26 into the processing space 21B to prevent the oxygen or the product containing the oxygen from flowing backward to the remote radical source 26.

Further, for removing the oxygen or the product containing the oxygen flowing backward to the remote plasma source 26 as mentioned above, there is a method for performing, e.g., a vacuum purge or a gas purge by an inactive gas.

For example, the vacuum purge is a method of removing the oxygen remaining in the processing space 21B or the remote plasma source 26 by vacuum-exhausting the processing space to a low pressure (a high vacuum) state after terminating the oxidation processing.

In the same manner, the gas purge is a method of removing the oxygen remaining in the processing space 21B or the remote plasma source 26 by introducing the inactive gas into the processing space 21B after terminating the oxidation process.

Generally, the vacuum purge and the gas purge are combined to be performed several times. However, if the vacuum purge and the gas purge are performed, the processing time is required, resulting in a problem that throughput of the substrate processing apparatus 20 is reduced and productivity is lowered. Further, since the expensive exhaust means having a high pumping rate of, e.g., a turbo molecular pump or the like is required, there is a problem of cost increase for the apparatus.

In the present embodiment, it is possible to eliminate the influence of the residual oxygen as mentioned above, without lowering throughput of the apparatus.

Further, after the oxidation process shown in FIGS. 16A and 16B, the nitridation process described in FIGS. 15A and 15B is performed to nitride the base oxide film, and to thereby form the oxynitride film. At that time, since the influence of a back flow of the oxygen to the remote plasma source 26 is eliminated as mentioned above, such a phenomenon that the oxidation due to the residual oxygen or the product containing the oxygen is progressed to thereby grow the base oxide film is suppressed. Hence, the nitridation is progressed, and the oxynitride film having a desired nitrogen concentration can be formed.

As a result, it is possible to form the extremely thin base oxide film 202 of, e.g., about 0.4 nm, appropriate to be used in the semiconductor device 200 described in FIG. 3, and to form the oxynitride film 202A having a proper concentration on the base oxide film.

Further, the purge gas used in the present embodiment may be any inactive gas, and nitrogen, helium and the like as well as the above-described Ar gas can be used.

### Ninth Embodiment

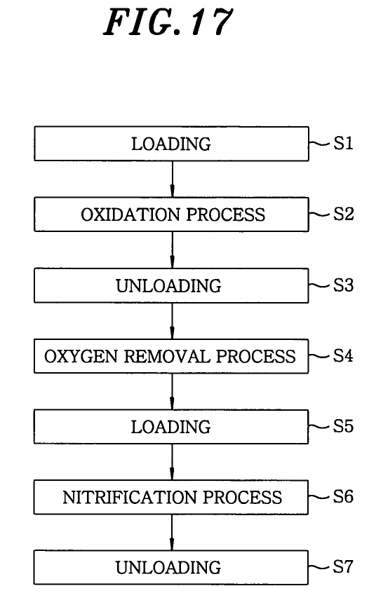

Next, as a ninth embodiment of the present invention, additional method of suppressing the film growth of the base oxide film 202 in the forming processing of the oxynitride film, when forming the extremely thin base oxide film 202 including the oxynitride film 202A on the silicon substrate 201 of FIG. 3, will be shown in a flowchart of FIG. 17. In the following explanation, a case of using the substrate processing apparatus 20A as an example of the substrate processing will be shown.

Referring to FIG. 17, first, the substrate W to be processed of a substrate to be processed is loaded into the substrate processing vessel 21 and mounted on the substrate supporting table 22, at step 1 (indicated as S1 in the drawing, the same as above).

Subsequently, at step 2, as described above in FIGS. 14A and 14B, the surface of the substrate W to be processed of the silicon substrate is oxidized, so that an extremely thin oxide film having a film thickness of 1 nm or less, particularly about 0.4 nm, equivalent to 2˜3 atomic layers is formed stably and reproducibly on the surface of the silicon substrate.

Thereafter, at step 3, the substrate W to be processed is unloaded from the processing vessel 21.

At a following step 4, in the substrate processing vessel 21 from which the substrate W to be processed has been unloaded, the residual oxygen removal is carried out from the corresponding substrate processing vessel 21. In the oxidation process of step 2, the oxygen is supplied into the processing space 21B of an inside of the processing vessel 21, and the oxygen radicals are formed. As a result, the oxygen or the products containing oxygen, e.g., H₂O and the like, remains in the processing space 21B or a space connected to the corresponding processing space 21B.

Therefore, in the present step, a removal processing of the oxygen or the product containing the oxygen is carried out.

Specifically, in the same method as the nitridation processing described in FIGS. 15A and 15B, while the substrate W to be processed is unloaded from the processing vessel 21, an activated Ar gas and the nitrogen gas containing Ar radicals and nitrogen radicals produced by dissociating the Ar gas and the nitrogen gas through the remote plasma source 26 are supplied into the processing space 21B and discharged from the gas exhaust port 21A, so that the oxygen or the products containing oxygen, e.g., H₂O and the like, which remains in the processing space 21B or a space connected to the corresponding processing space 21B, e.g., an inside of the remote plasma source 26 and the like, is discharged from the gas exhaust port 21A.

Subsequently, at step 5, the substrate W to be processed is loaded again into the processing vessel 21, and mounted on the substrate supporting table 22.

Continuously, at step 6, as shown in FIGS. 15A and 15B, the surface of the substrate W to be processed on which the base oxide film was formed at step 2 is nitrided by the nitrogen radicals to form the oxynitride film. In this case, it is possible to perform a nitridation while suppressing the influence of the film growth of the oxide film, since the oxygen removal process was performed at step 4.

Namely, oxygen, the products containing oxygen, and the like, which were used for the oxidation at step 2 and remain in the inside of the processing vessel 21, the processing space 21B, and the space connected to the corresponding processing space 21B, e.g., the inside of the remote plasma source 26 and the like, are removed. Therefore, in the nitridation processing of the present step, it is possible to resolve such problems that the oxide film is grown by the oxygen and the residues containing the oxygen, which were used at step 2, and the nitrogen concentration becomes lower on the nitridation. Hence, the nitridation progresses, so that it is possible to form the oxynitride film having a desired nitrogen concentration.

As a result, it is possible to form the extremely thin base oxide film 202 of, e.g., about 0.4 nm, appropriate to be used in the semiconductor device 200 described in FIG. 3, and to form the oxynitride film 202A having a proper concentration on the base oxide film.

Next, the substrate W to be processed is unloaded from the processing vessel 21 at step 7, and the processing is terminated.

Generally, the vacuum purge or the gas purge by the inactive gas may be performed, in order to remove oxygen, the products containing oxygen, and the like, which were used for the oxidation at step 2 and remain in the inside of the processing vessel 21, the processing space 21B, and the space connected to the corresponding processing space 21B, e.g., the inside of the remote plasma source 26 and the like, as described above.

For example, the vacuum purge is a method of removing the oxygen or the product containing the oxygen remaining in the processing space 21B or the space connected to the corresponding remote plasma source 26, by vacuum-exhausting the processing space to a low pressure (a high vacuum) state after terminating the oxidation processing.

In the same manner, the gas purge is a method of removing the oxygen remaining in the processing space 21B or the space connected to the corresponding remote plasma source 26, by introducing the inactive gas into the processing space 21B after terminating the oxidation processing.

Conventionally, effects are obtained by combining the vacuum purge and the gas purge to be performed several times. However, if the vacuum purge and the gas purge are performed repeatedly, the processing time is required. Hence, throughput of the substrate processing apparatus 20A is reduced and productivity is declined.

Further, since the expensive exhaust means with a high exhaust velocity and effective for the vacuum purge is required in order to perform the vacuum purge, there is a problem of cost increase for the apparatus.

In the present embodiment, it is possible to eliminate the influence of the residual oxygen as mentioned above, without lowering throughput of the apparatus.

Further, the aforementioned substrate processing method in accordance with the present embodiment may be carried out, e.g., in a cluster type substrate processing system that will be described below.

### Tenth Embodiment

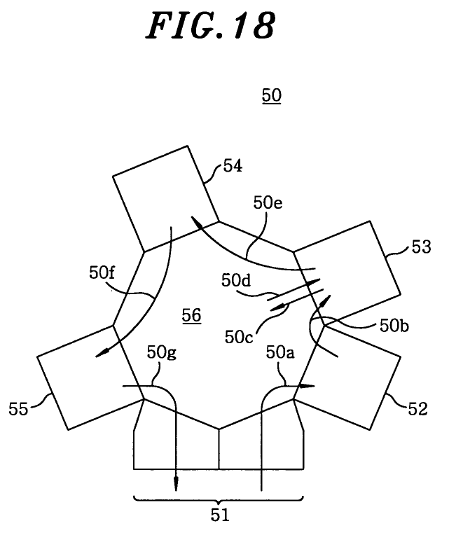

FIG. 18 shows a configuration of a cluster type substrate processing system 50 in accordance with a tenth embodiment of the present invention.

Referring to FIG. 18, the cluster type substrate processing system 50 is configured such that a vacuum transfer chamber 56 is connected to a load lock chamber 51 for loading/unloading the substrate; a pre-processing chamber 52 for removing a natural oxide film and a carbon contamination from the surface of the substrate; a processing chamber 53 formed of the substrate processing apparatus 20A of FIG. 13; a CVD processing chamber 54 for depositing on the substrate the high-K film such as Ta₂O₅, Al₂O₃, ZrO₂, HfO₂, ZrSiO₄ or HfSiO₄; and a cooling chamber 55 for cooling the substrate. In the vacuum transfer chamber 56, a transfer arm (not shown) is installed.

In case of performing the substrate processing method of the present embodiment, first, the substrate W to be processed that has been loaded into the load lock chamber 51 is loaded into the pre-processing chamber 52 along a path 50a, so that the natural oxide film and the carbon contamination are removed. The substrate W to be processed, from which the natural oxide film and the carbon contamination have been removed in the pre-processing chamber 52, is loaded into the processing chamber 53 along a path 50b at step 1, and the base oxide film is formed with a uniform thickness equivalent to 2˜3 atomic layers by the substrate processing apparatus 20A of FIG. 13, at step 2.

The substrate W to be processed on which the base oxide film has been formed in the processing chamber 53 is transferred to the vacuum transfer chamber 56 along a path 50c at step 3, and at step 4, the oxygen removal process discussed in the ninth embodiment is performed by the substrate processing apparatus 20A while the substrate W to be processed is maintained in the vacuum transfer chamber 56.

After that, at step 5, the substrate W to be processed is transferred from the transfer chamber 56 to the processing chamber 53 along a path 50d and, the nitridation of the base oxide film is carried out by the substrate processing apparatus 20A to form the oxynitride film at step 6.

Subsequently, at step 7, the substrate W to be processed is unloaded from the processing chamber 53 along a path 50e and introduced into the CVD processing chamber 54, so that a high-K gate insulating film is formed on the base oxide film.

Further, the substrate to be processed is transferred from the CVD processing chamber 54 to the cooling chamber 55 along a path 50f, cooled in the cooling chamber 55, and then, returned to the load lock chamber 51 along a path 50g to thereby be unloaded to the outside.

Still further, additional pre-processing chamber for performing a flattening processing on the silicon substrate under Ar atmosphere by the high temperature heat treatment may be provided in the substrate processing system 50 of FIG. 18.

As mentioned above, by the cluster type substrate processing system 50, the substrate processing method described in the ninth embodiment can be feasible, and such a phenomenon that the oxidation due to the oxygen or the product containing the oxygen remaining in the processing vessel 21 is progressed to thereby grow the base oxide film in the nitridation process is suppressed, and the nitridation is progressed. Therefore, it is possible to form the oxynitride film having a desired nitrogen concentration.

As a result, it is possible to form the extremely thin base oxide film 202 of, e.g., about 0.4 nm, appropriate to be used in the semiconductor device 200 described in FIG. 3, and to form the oxynitride film 202A having a proper concentration on the base oxide film. By suppressing the film growth of the base oxide film, the nitridation is facilitated, and thus the oxynitride film can be formed with a desired nitrogen concentration.

Further, in the oxygen removal process of step 4, a place where the substrate W to be processed is mounted is not limited to the vacuum transfer chamber 56. For example, the pre-processing chamber 52, the cooling chamber 55, the load lock chamber 51 or the like, may be used as long as it is shut off from the air to thereby prevent the contamination or the oxidation of the substrate W to be processed, and it is a space capable of transferring and unloading.

### Eleventh Embodiment

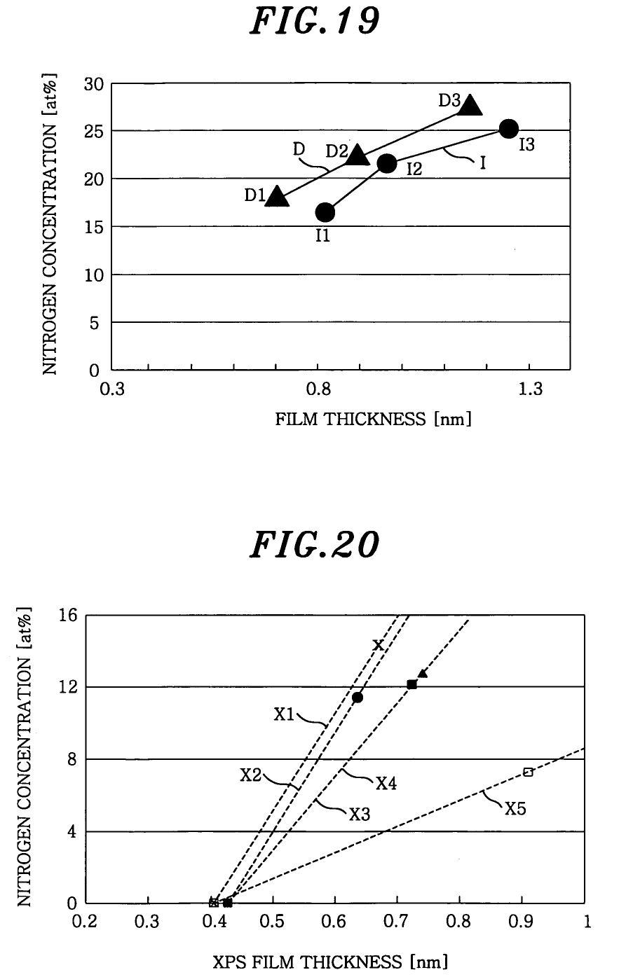

Next, as an eleventh embodiment of the present invention, a relationship between the film thickness and the nitrogen concentration will be shown in FIG. 19, in case where the base oxide film is formed and the oxynitride film is formed by nitriding the base oxide film by performing the substrate processing method of the ninth embodiment, through the cluster type substrate processing system 50 described in the prior tenth embodiment.

Further, for comparison, a result will be also mentioned in the drawing, wherein the oxygen removal process of the ninth embodiment is not carried out and, the formation of the base oxide film and the nitridation of the corresponding base oxide film are performed consecutively, i.e., in a case where the formation processing of the base oxide film described in FIGS. 14A and 14B and the nitridation processing of FIGS. 15A and 15B are carried out consecutively.

FIG. 19 describes experimental results performed, wherein in experiments D1 through D3, the substrate processing method mentioned in the ninth embodiment was used while in experiments I1 through I3, the formation of the base oxide film and the nitridation of the corresponding base oxide film were consecutively performed. Further, substrate processing conditions of the experiments D1 through D3 and I1 through I3 will be shown in the following <Table 1>.

TABLE 1

| | Formation of base oxide film | | | | | Formation of oxynitride film | | | | |
|---|---|---|---|---|---|---|---|---|---|---|
| | | | | processing | Oxygen removal | | | | | processing |
| | O2 | pressure | temperature | time | process | Ar | N₂ | pressure | temperature | time |
| I1 | 0.3 slm | 0.02 Torr | 500° C. | 300 sec | → | 1.38 slm | 0.075 slm | 0.081 Torr | 500° C. | 25 sec |
| I2 | 0.3 slm | 0.02 Torr | 500° C. | 300 sec | → | 1.38 slm | 0.075 slm | 0.081 Torr | 500° C. | 60 sec |
| I2 | 0.3 slm | 0.02 Torr | 500° C. | 300 sec | → | 1.38 slm | 0.075 slm | 0.081 Torr | 500° C. | 180 sec |
| D1 | 0.3 slm | 0.02 Torr | 500° C. | 300 sec | RFN Ar: 1.38 slm, | 1.38 slm | 0.075 slm | 0.081 Torr | 500° C. | 25 sec |
| | | | | | N2: 0.075 slm, 10 min | | | | | |
| D2 | 0.3 slm | 0.02 Torr | 500° C. | 300 sec | RFN Ar: 1.38 slm, | 1.38 slm | 0.075 slm | 0.081 Torr | 500° C. | 60 sec |
| | | | | | N2: 0.075 slm, 10 min | | | | | |
| D3 | 0.3 slm | 0.02 Torr | 500° C. | 300 sec | RFN Ar: 1.38 slm, | 1.38 slm | 0.075 slm | 0.081 Torr | 500° C. | 180 sec |
| | | | | | N2: 0.075 slm, 10 min | | | | | |

In any case of the experiments D1 through D3 and I1 through I3, the condition for forming the base oxide film was the same, and the processing was carried out by the aforementioned method of FIGS. 14A and 14B, with an oxygen flow rate, a pressure, a temperature of the substrate supporting table, and a processing time, which are described in Table 1.

Further, in case of the experiments I1 through I3, the nitridation process was performed under the conditions of an Ar flow rate, a nitrogen flow rate, a pressure, a temperature of substrate supporting table, and a processing time, which are described in Table 1. In case of the experiments I1 through I3, the oxygen removal process was not carried out.

In case of the experiments D1 through D3, the oxygen removal process was performed under the conditions of an Ar flow rate, and a processing time, which are described in Table, and then, the nitridation process was carried out under the conditions described in the Table 1.

Referring to FIG. 19, in case of the experiments D1 through D3 in which the oxygen removal process mentioned in the ninth embodiment was carried out, it can be noted that respective increases in the film thickness when nitriding the base oxide film were small, compared with those in the experiments I1 through I3 in which the oxygen removal was not carried out. Further, it can be known that the nitrogen concentration was high and the nitridation was sufficiently facilitated.

This means that if the oxygen removal process is carried out, as described above, the film growth phenomenon of the base oxide film due to the residual oxygen is suppressed in the nitridation process, and the nitridation is facilitated to thereby form the oxynitride film having a desired nitrogen concentration.

### Twelfth Embodiment

Next, as a twelfth embodiment of the present invention, a relationship between the film thickness and the nitrogen concentration will be shown in FIG. 20 for experiments X1 through X5 that will be discussed later, in case where the base oxide film is formed and the oxynitride film is formed by nitriding the corresponding base oxide film by using the substrate processing apparatus 20A, while varying the conditions.

Further, substrate processing conditions of the experiments X1 through X5 will be described in the following (Table 2).

TABLE 2

| | Formation of base oxide film | | | | | | Formation of oxynitride film | | | | |
|---|---|---|---|---|---|---|---|---|---|---|---|
| | | | | | processing | Oxygen removal | | | | | processing |
| | Purge Ar | O₂ | pressure | temperature | time | process | AR | N₂ | pressure | temperature | time |
| X1 | 0.1 slm | 0.3 slm | 0.023 Torr | 500° C. | 300 sec | → | 1.38 slm | 0.075 slm | 0.081 Torr | 500° C. | 60 sec |
| X2 | — | 0.3 slm | 0.02 Torr | 500° C. | 300 sec | RFN Ar: 1.38 slm, | 1.38 slm | 0.075 slm | 0.081 Torr | 500° C. | 60 sec |
| | | | | | | N₂: 0.075 slm, 5 min | | | | | |
| X3 | — | 0.3 slm | 0.02 Torr | 500° C. | 300 sec | unloading and | 1.38 slm | 0.075 slm | 0.081 Torr | 500° C. | 60 sec |
| | | | | | | loading again | | | | | |
| X4 | — | 0.3 slm | 0.02 Torr | 500° C. | 300 sec | → | 1.38 slm | 0.075 slm | 0.081 Torr | 500° C. | 60 sec |
| X5 | — | 0.3 slm | 0.02 Torr | 500° C. | 300 sec | RFO Ar: 0.8 slm, | 1.38 slm | 0.075 slm | 0.081 Torr | 500° C. | 60 sec |
| | | | | | | O₂: 0.005 slm, 30 sec | | | | | |

Rotation: 20 rpm

In case of the experiment X1, the base oxide film was formed under such conditions described in Table 2 as an Ar flow rate of the purge gas, an oxygen flow rate, a pressure, a temperature of the substrate supporting table, and a processing time, by employing the method for forming the base oxide film mentioned in FIGS. 16A and 16B, i.e., the method for preventing the back flow of the oxygen by introducing the purge gas from the remote plasma source 26. After that, by using the method described in FIGS. 15A and 15B, the oxynitride film was formed with an Ar flow rate, a nitrogen flow rate, a pressure, a temperature of the substrate supporting table and processing time described in Table 2.

In case of the experiments X2 through X5, the base oxide film was formed under the above-described conditions of an oxygen flow rate, a pressure, a temperature of the substrate supporting table, and a processing time, by applying the method for forming the base oxide film mentioned in FIGS. 14A and 14B, and then, by using the nitriding method described in FIGS. 15A and 15B, the oxynitride film was formed under the aforementioned conditions of an Ar flow rate, a nitrogen flow rate, a pressure, a temperature of the substrate supporting table and a processing time.

However, in case of the experiment X2, the oxygen removal process was performed under the conditions described in Table 2 such as an Ar flow rate, a nitrogen flow rate, and a processing time, in accordance with the substrate processing method described in the ninth embodiment.

Further, in case of the experiment X3, the wafer was unloaded from the processing vessel 21 after terminating the formation of the base oxide film, and directly loaded again into the processing vessel 21 to perform the oxynitride film formation processing.

In case of the experiment X4, after terminating the formation of the base oxide film, the nitridation processing was carried out continuously without unloading the substrate W to be processed.

In case of the experiment X5, for examining the influence of the residual oxygen while forming the oxynitride film, first, the substrate W to be processed was unloaded after forming the base oxide film. Then, in the substrate processing apparatus 20A, the oxygen radical processing was carried out by introducing the oxygen under the above-described conditions in Table 2, and then, the substrate W to be processed was loaded again to form the oxynitride film.

Referring to FIG. 20, in case of observing any trend of the nitrogen concentration with respect to the increase of the film thickness, the cases of the experiments X1 and X2 represent substantially same trend with each other, and it is considered that the film growth of the base oxide film is suppressed in the nitridation processing and the nitridation is facilitated to thereby increase the nitrogen concentration, compared as those of the experiments X3 through X5 that will be discussed later.

In case of the experiment X1, by performing the method for forming the base oxide film mentioned in FIGS. 16A and 16B, the oxygen or the oxygen radicals and the products containing the oxygen are prevented from flowing backward to the remote plasma source 26 of a radical source for the nitridation, when oxidizing the silicon substrate. As a result, in the nitridation processing after forming the base oxide film, the influence of the residual oxygen or the product containing the oxygen is eliminated to thereby suppress the increase of the base oxide film. Further, the nitridation is facilitated, so that the oxynitride film can be formed with a high nitrogen concentration.

Further, in case of the experiment X2, through the oxygen removal process, i.e., by the activated Ar gas and the nitrogen gas containing the Ar radicals and the nitrogen radicals, the oxygen or the product containing the oxygen such as H₂O and the like, which remains in the processing space 21B or the space connected to the corresponding processing space 21B, e.g., the inside of the remote plasma source 26 and the like, is removed and, in the nitridation process after forming the base oxide film, the influence of the residual oxygen or the product containing the oxygen is eliminated to thereby suppress the increase of the oxide film. Further, the nitridation is facilitated, so that the oxynitride film can be formed with a high nitrogen concentration.

Still further, the experiments X3 and X4 represent substantially same trend in a relationship between the film thickness and the nitrogen concentration. From this, it can be noted that just unloading the substrate W to be processed from the processing vessel 21 and loading it thereinto will not do any in removing the residual oxygen described above. Therefore, the oxygen removal process as mentioned above is needed therefore.

Meanwhile, for confirming the influence of the residual oxygen on the nitridation, in case of the experiment X5, the oxygen radicals are supplied into the processing vessel 21 after terminating the formation of the base oxide film. In case of the experiment X5, the film growth of the base oxide film is large and the nitrogen concentration is small, so that the oxygen and the product containing the oxygen remaining in the processing space 21B and the space connected to the processing space 21B oxidize the silicon substrate in the nitridation processing to thereby cause the film growth of the base oxide film, whereby it is considered that the nitridation is not facilitated and the nitrogen concentration is small.

Still further, the substrate processing methods described in the ninth and the tenth embodiment, for example, may be performed by using the substrate processing apparatus 20. Alternatively, the method for preventing the back flow of the oxygen by using the purge gas described in the eighth embodiment and the oxygen removal process described in the ninth and the tenth embodiment may be combined to be performed. In that case, such a phenomenon that the oxidation is progressed due to oxygen or the products containing oxygen, whereby the base oxide film is grown, is suppressed. Further, the nitrification is progressed, so that the oxynitride film can be formed with a desired nitrogen concentration.

As a result, it is possible to form the extremely thin base oxide film 202 of, e.g., about 0.4 nm, appropriate to be used in the semiconductor device 200 described in FIG. 3, and to form the oxynitride film 202A having a desired concentration on the base oxide film.

While the invention has been shown and described with respect to the preferred embodiments, it will be understood by those skilled in the art that various changes and modifications may be made without departing from the spirit and scope of the invention as defined in the following claims.

Further, The present application is based upon and claims the benefit of priority from the prior Japanese Patent Application No. 2003-72650 filed on Mar. 17, 2003, the entire contents of which are incorporated herein by reference.

What is claimed is:

1. A substrate processing apparatus comprising:
a processing vessel forming a processing space;
a rotatable supporting table for supporting a substrate to be processed in the processing space;
a rotation mechanism of the supporting table;
a nitrogen radical generation unit, provided at an end portion of the processing vessel at a first side of the supporting table, for forming nitrogen radicals by a high frequency plasma and supplying the nitrogen radicals into the processing space, the nitrogen radicals flowing along a surface of the substrate to be processed from the first side to a second side, the second side facing the first side with the substrate to be processed placed therebetween;
an oxygen radical generation unit, provided at the end portion at the first side, for forming oxygen radicals by a high frequency plasma and supplying the oxygen radicals into the processing space, the oxygen radicals flowing along the surface of the substrate to be processed from the first side to the second side; and
a gas exhaust path, provided at an end portion at the second side, to exhaust the processing space,
wherein the nitrogen radicals and the oxygen radicals flow towards the gas exhaust path from the nitrogen radical generation unit and the oxygen radical generation unit while forming a nitrogen radical flow path and an oxygen radical flow path along the surface of the substrate to be processed, respectively.

2. The substrate processing apparatus of claim 1, wherein the nitrogen radical generation unit includes a first gas passageway and a first high frequency plasma generation unit formed at a part of the first gas passageway to excite a nitrogen gas passing therethrough into a plasma; and the oxygen radical generation unit includes a second gas passageway and a second high frequency plasma generation unit formed at a part of the second gas passageway to excite an oxygen gas passing therethrough into a plasma,
wherein the first and the second gas passageway are in communication with the processing space.

3. The substrate processing apparatus of claim 1, wherein the nitrogen radical flow path and the oxygen radical flow path are substantially parallel to each other.

4. The substrate processing apparatus of claim 1, wherein the nitrogen radical generation unit is installed to allow the distance between a center of the nitrogen radical flow path and that of the substrate to be processed to be 40 mm or less.

5. The substrate processing apparatus of claim 1, wherein the oxygen radical generation unit is installed to allow the distance between a center of the oxygen radical flow path and that of the substrate to be processed to be 40 mm or less.

6. The substrate processing apparatus of claim 1, wherein a center of the nitrogen radical flow path intersects with that of the oxygen radical flow path substantially at a center of the substrate to be processed.

7. The substrate processing apparatus of claim 1, wherein there is provided a flow adjusting plate interfering with the nitrogen radical flow path to change a direction thereof.

8. The substrate processing apparatus of claim 1, wherein there is provided a flow adjusting plate interfering with the oxygen radical flow path to change a direction thereof.

9. A substrate processing method for use in a substrate processing apparatus, which includes a processing vessel forming a processing space and having a supporting table for supporting a substrate to be processed in the processing space; a first radical generation unit for supplying first radicals into the processing vessel, the first radicals flowing along a surface of the substrate to be processed from a first side of the processing vessel to a second side that faces the first side with the substrate to be processed placed therebetween; and a second radical generation unit for supplying second radicals into the processing space, the second radicals flowing along the surface of the substrate to be processed from the first side to the second side, the method comprising:
a first process of processing the substrate to be processed by supplying the first radicals from the first radical generation unit into the processing space while introducing a purge gas purging the second radical generation unit into the processing space from the second radical generation unit; and
a second process of processing the substrate to be processed by introducing the second radicals from the second radical generation unit into the processing space.

10. The substrate processing method of claim 9, wherein the substrate to be processed is a silicon substrate; and, in the first process, the surface of the silicon substrate is oxidized by the first radicals to form an oxide film, the first radicals being oxygen radicals.

11. The substrate processing method of claim 10, wherein, in the second process, a surface of the oxide film is nitrided by the second radicals to form an oxynitride film, the second radicals being nitrogen radicals.

12. The substrate processing method of claim 9, wherein the first and the second radicals are supplied by being carried by a gas stream flowing from the first side to the second side along the surface of the substrate to be processed, and exhausted at the second side.

13. The substrate processing method of claim 9, wherein the first radical generation unit forms oxygen radicals by a high frequency plasma.

14. The substrate processing method of claim 9, wherein the first radical generation unit includes an ultraviolet light source forming oxygen radicals.

15. The substrate processing method of claim 9, wherein the second radical generation unit forms nitrogen radicals by a high frequency plasma.

16. The substrate processing method of claim 15, wherein the second radical generation unit includes a gas passageway, and a high frequency plasma generation unit formed at a part of the gas passageway to excite a nitrogen gas passing therethrough into a plasma.

17. The substrate processing method of claim 16, wherein the purge gas is supplied through the gas passageway.

18. The substrate processing method of claim 9, wherein the purge gas is an inactive gas.

19. A substrate processing method comprising:
a first process for performing a first processing on a substrate to be processed in a processing vessel;
a second process for unloading the substrate from the processing vessel;
a third process for performing an oxygen removal process from the processing vessel;
a fourth process for loading the substrate into the processing vessel; and
a fifth process for performing a second processing on the substrate.

20. The substrate processing method of claim 19, wherein, in the oxygen removal process, a processing gas is excited into a plasma and introduced into the processing vessel, and the processing gas is exhausted from the processing vessel.

21. The substrate processing method of claim 20, wherein the processing gas is an inactive gas.

22. The substrate processing method of claim 19, wherein the substrate to be processed is a silicon substrate, and the first processing is an oxidation process for oxidizing a surface of the silicon substrate to form an oxide film.

23. The substrate processing method of claim 22, wherein the second processing is a nitridation process for nitriding the oxide film to form an oxynitride film.

24. The substrate processing method of claim 23, wherein the processing vessel has an oxygen radical generation unit and a nitrogen radical generation unit; the oxidation process is carried out by oxygen radicals formed by the oxygen radical generation unit; and the nitridation process is performed by nitrogen radicals formed by the nitrogen radical generation unit.

25. The substrate processing method of claim 20, wherein the plasma excitation is carried out in the nitrogen radical generation unit, and a processing gas excited into a plasma is introduced from the nitrogen radical generation unit into the processing vessel.

26. The substrate processing method of claim 24, wherein the oxygen radicals and the nitrogen radicals flow along the substrate to be processed, and are exhausted from a gas exhaust port installed at an opposite side to the oxygen radical generation unit and the nitrogen radical generation unit along a diametrical direction of the substrate to be processed, which is mounted in the processing vessel.

27. The substrate processing method of claim 19, wherein the processing vessel is connected to a cluster substrate processing system in which a plurality of substrate processing apparatus are connected to a transfer chamber.

28. The substrate processing method of claim 27, wherein the substrate is transferred from the processing vessel to the substrate transfer chamber in the second processing.

29. The substrate processing method of claim 27, wherein the substrate is mounted in the substrate transfer chamber in the third processing.

30. The substrate processing method of claim 27, wherein the substrate is transferred from the transfer chamber to the substrate processing vessel in the fourth processing.
